(19) United States
(12) Patent Application Publication
(10) Pub. No.: US 2013/0084459 A1
(43) Pub. Date: Apr. 4, 2013

(54) LOW PEEL ADHESIVE

(71) Applicants: Eric G. Larson, Lake Elmo, MN (US); Blake R. Dronen, New Brighton, MN (US); Miguel A. Guerra, Woodbury, MN (US); Wayne S. Mahoney, St. Paul, MN (US); Richard J. Webb, Inver Grove Heights, MN (US)

(72) Inventors: Eric G. Larson, Lake Elmo, MN (US); Blake R. Dronen, New Brighton, MN (US); Miguel A. Guerra, Woodbury, MN (US); Wayne S. Mahoney, St. Paul, MN (US); Richard J. Webb, Inver Grove Heights, MN (US)

(73) Assignee: 3M Innovative Properties Company

(21) Appl. No.: 13/249,501

(22) Filed: Sep. 30, 2011

(51) Int. Cl. C09J 127/12; H01L 21/31; B32B 38/10; B32B 27/00; B32B 37/12

(52) U.S. Cl. 428/422; 522/64; 106/287.24; 156/333; 156/712; 438/758; 257/E21.24

(57) ABSTRACT

A curable adhesive composition is disclosed comprising: at least one free radically polymerizable oligomer component; optionally at least one diluent monomer; at least one perfluorinated ether monomer; and a photoinitiator. The curable liquid adhesive is easily removable with low force and low adhesive transfer.

### FIELD OF THE INVENTION

This disclosure provides an adhesive that yields sufficient shear with low peel adhesion values. More specifically this invention relates to a curable liquid adhesive that is easily removable with low force and low adhesive transfer.

### BACKGROUND OF THE INVENTION

Liquid adhesives that can be used to bond substrates together yet remain peelable after curing and subsequent processing of the bonded assemblies have many commercial uses. Ideally, depending upon the substrate, the adhesive must provide adequate peel strength to prevent damage to the surface of the substrate when the adhesive is removed and appropriate cohesive strength to control the transfer of adhesive to the substrate. Balancing these adhesive properties, particularly in a removable adhesive, poses difficulty to the formulator. For example, some adhesives may permit the removal of a backing from a contact surface to which it had been adhered, but they do not have sufficient shear to withstand necessary processing. Other adhesives may adhere too strongly and cause the backing to tear on removal.

In the processing of semiconductor wafers, various adhesive tapes that are reportedly useful in semiconductor wafer backside grinding operations (sometimes referred to herein as “wafer grinding”) have been described. For example, U.S. Pat. No. 4,853,286 discloses a wafer processing film that is used in the grinding of wafers to prevent breakage. The film includes a base film, a layer of a commercially available, common adhesive (such as an acrylic, ester, urethane or synthetic rubber adhesive), and an optional supporting film laminated to the non-adhesive side of the base film. U.S. Pat. No. 5,126,178 (Takemura et al.) describes a wafer processing film that includes a base film with an adhesive on one side (which is protected by a removable release film), and a phosphoric acid-based surfactant on the backside. The adhesive can be acryl-based, vinyl-based, or rubber-based, although an aqueous emulsion type pressure sensitive adhesive is preferred. Disclosed in U.S. Pat. No. 5,183,699 (Takemura et. al) is a wafer processing film which is used when grinding wafers so as to prevent breakage. The wafer processing film includes a base film and a layer of adhesive (e.g., a conventional acrylic or rubber-based adhesive) on the base film. A synthetic resin film, which has a surface roughness not greater than 2 μm, is arranged on the adhesive layer.

However, there still remains a need for an adhesive that has even greater utility in semiconductor wafer grinding processes, in particular allowing a substrate to be bonded to a rigid carrier for backgrinding and further processing. Preferably, such an adhesive will possess several desirable properties. For example, the adhesive should provide sufficient adhesion to surfaces such as silicon, polyimide, silicon oxynitride and photoresist coatings such that the semiconductor wafers will readily survive post-processing steps yet be easily removed when required. However, the final adhesion should not be so high that removing the adhesive breaks or fractures a larger number of wafers than is permitted under conventional industry standards (typically about one wafer or less per thousand), or leaves adhesive residue that could impair subsequent processing of the wafer.

It would also be desirable if the initial and final adhesion properties of the adhesive were maintained over several days and, more preferably, over several weeks of storage. That is, there should be no process or material-limiting increase in adhesion over time (sometimes preferred to as adhesion build), a problem associated with certain adhesives. Similarly, there should be no other significant change in adhesion over time, as could occur if surfactants and other mobile components in the adhesive migrate to the adhesive bond line so as to form a weak boundary layer. An adhesive that maintains its initial and final adhesion properties after bonding would not only provide assemblies having long shelf lives, but would also eliminate the need to carry out the grinding process shortly after bonding the semiconductor wafers.

Another desirable attribute would be the ability to remove the adhesive without staining, which refers to a change in the semiconductor wafer that is detected when the semiconductor wafer is viewed under a microscope and which may be the result of either microscopic amounts of adhesive residue being left on the passivation layer or partial removal of the passivation layer. It would also be helpful if the adhesive were insensitive to water so as to prevent the wafer from being loosened by the water spray used during grinding.

### SUMMARY

The present invention involves adhesives that have sufficient shear properties, low peel adhesion and exhibit minimal adhesive transfer. The disclosure provides a curable liquid adhesive that can used to bond two substrates together with sufficient resistance to shear forces while still being easily peeled from the substrates, even after prolonged periods of time. In accordance with this invention, a curable composition is provided comprising at least one radiation curable oligomer (“oligomer component”); optionally at least one diluent monomer; at least one polymerizable perfluorinated ether monomer; and a photoinitiator, which may be cured to provide the adhesives.

When used as an adhesive in wafer processing applications, the adhesive disclosed herein reduces the problem of void and bubble formation and persistence in the joining layer during vacuum processing.

As used herein:

“acryloyl” is inclusive of both esters and amides.

“(meth)acryloyl” includes both acryloyl and methacryloyl groups; i.e. is inclusive of both esters and amides.

“curable” means that a coatable material can be transformed into a solid, substantially non-flowing material by means of free-radical polymerization, chemical cross linking, radiation crosslinking, or the like.

“alkyl” includes straight-chained, branched, and cycloalkyl groups and includes both unsubstituted and substituted alkyl groups. Unless otherwise indicated, the alkyl groups typically contain from 1 to 20 carbon atoms. Examples of “alkyl” as used herein include, but are not limited to, methyl, ethyl, n-propyl, n-butyl, n-pentyl, isobutyl, t-butyl, isopropyl, n-octyl, n-heptyl, ethylhexyl, cyclopentyl, cyclohexyl, cycloheptyl, adamantyl, and norbornyl, and the like. Unless otherwise noted, alkyl groups may be mono- or polyvalent, i.e. monvalent alkyl or polyvalent alkylene.

“heteroalkyl” includes both straight-chained, branched, and cyclic alkyl groups with one or more heteroatoms independently selected from S, O, and N with both unsubstituted and substituted alkyl groups. Unless otherwise indicated, the heteroalkyl groups typically contain from 1 to 20 carbon atoms. “Heteroalkyl” is a subset of “hydrocarbyl containing one or more S, N, O, P, or Si atoms” described below. Examples of “heteroalkyl” as used herein include, but are not limited to, methoxy, ethoxy, propoxy, 3,6-dioxaheptyl, 3-(trimethylsilyl)-propyl, 4-dimethylaminobutyl, and the like. Unless otherwise noted, heteroalkyl groups may be mono- or polyvalent, i.e. monovalent heteroalkyl or polyvalent heteroalkylene.

“aryl” is an aromatic group containing 5-18 ring atoms and can contain optional fused rings, which may be saturated, unsaturated, or aromatic. Examples of an aryl groups include phenyl, naphthyl, biphenyl, phenanthryl, and anthracyl. Heteroaryl is aryl containing 1-3 heteroatoms such as nitrogen, oxygen, or sulfur and can contain fused rings. Some examples of heteroaryl groups are pyridyl, furanyl, pyrrolyl, thienyl, thiazolyl, oxazolyl, imidazolyl, indolyl, benzofuranyl, and benzthiazolyl. Unless otherwise noted, aryl and heteroaryl groups may be mono- or polyvalent, i.e. monovalent aryl or polyvalent arylene.

“(hetero)hydrocarbyl” is inclusive of hydrocarbyl alkyl and aryl groups, and heterohydrocarbyl heteroalkyl and heteroaryl groups, the later comprising one or more catenary oxygen heteroatoms such as ether or amino groups. Heterohydrocarbyl may optionally contain one or more catenary (in-chain) functional groups including ester, amide, urea, urethane, and carbonate functional groups. Unless otherwise indicated, the non-polymeric (hetero)hydrocarbyl groups typically contain from 1 to 60 carbon atoms. Some examples of such heterohydrocarbyls as used herein include, but are not limited to, methoxy, ethoxy, propoxy, 4-diphenylaminobutyl, 2-(2′-phenoxyethoxy)ethyl, 3,6-dioxaheptyl, 3,6-dioxahexyl-6-phenyl, in addition to those described for “alkyl”, “heteroalkyl”, “aryl”, and “hetero aryl” supra.

### BRIEF DESCRIPTION OF DRAWINGS

FIG. 1 is a cross-sectional view showing a layered body of the present disclosure.

FIGS. 2a and 2b are cross-sectional views showing a vacuum adhesion device useful in the present disclosure.

FIG. 3 is a partial cross-sectional view of a grinding device useful in the method of the present disclosure.

FIGS. 4a, 4a′, 4b, 4c, 4d, and 4e are drawings showing the steps of separating the support and peeling the joining layer.

FIG. 5 is a cross-sectional view of a layered body fixing device which can be used in the laser beam irradiation step.

FIGS. 6a, 6b, 6c, 6d, 6e, and 6f are perspective views of a laser irradiation device.

FIGS. 7a and 7b are schematic views of a pick-up used in the operation of separating wafer and support.

FIG. 8 is a schematic view showing how the joining layer is peeled from the wafer.

### DETAILED DESCRIPTION

The present disclosure provides a curable adhesive composition comprising at least one radiation curable oligomer component; optionally at least one diluent monomer; at least one perfluorinated ether monomer; and a photoinitiator. The adhesives of this disclosure, i.e. the crosslinked compositions, provide the desired balance of low peel adhesion, and shear holding power. Desirably, the instant adhesives have peel values of less than 2 N/inch (˜7.9 N/dm), preferably less than 1 N/inch (˜3.9 N/dm) and more preferably less than 0.5 N/inch (˜1.9 N/dm).

The curable composition comprises one or more oligomeric radiation-curable components. Each monomeric or oligomeric component may comprise one or more reactive vinyl unsaturated moiety that will polymerize upon being exposed to suitable radiation; i.e. free-radically polymerizable. The oligomeric potion of the radiation curable oligomers have at least two, preferably at least 10, repeat units. However many such commercially available oligomers have undisclosed molecular weights and number of repeat units, and are characterized by viscosity. Such oligomers having viscosities in the range of at least 1000 centipoise, and generally a maximum of 20,000 centipoise.

Generally, radiation-curable components suitable for the practice of the present invention include free-radically polymerizable oligomers having the general formula

R^{Olig}-(L¹-Z¹)_{d}, wherein

R^{Olig} groups include urethanes, polyurethanes, esters, polyesters, polyethers, polyolefins, polybutadienes and epoxies;
Z¹ is a pendent, free-radically polymerizable group such as (meth)acryloyl, vinyl or alkynyl and is preferably a (meth)acrylate, and
d is greater than 1, preferably at least 2.

The linking group L¹ between the oligomer segment and ethylenically unsaturated end group includes a divalent or higher valency group selected from an alkylene, arylene, heteroalkylene, or combinations thereof and an optional divalent group selected from carbonyl, ester, amide, sulfonamide, or combinations thereof. L¹ can be unsubstituted or substituted with an alkyl, aryl, halo, or combinations thereof. The L¹ group typically has no more than 30 carbon atoms. In some compounds, the L¹ group has no more than 20 carbon atoms, no more than 10 carbon atoms, no more than 6 carbon atoms, or no more than 4 carbon atoms. For example, L¹ can be an alkylene, an alkylene substituted with an aryl group, or an alkylene in combination with an arylene or an alkyl ether or alkyl thioether linking group.

The pendent, free radically polymerizable functional groups Z¹ may be selected from the group consisting of vinyl, vinyl ether, ethynyl, and (meth)acyroyl which includes acrylate, methacrylate, acrylamide and methacrylamide groups.

The oligomeric group R^{olig} may be selected from poly(meth)acrylate, polyurethane, polyepoxide, polyester, polyether, polysulfide, polybutadiene, hydrogenated polyolefins (including hydrogenated polybutadienes, isoprenes and ethylene/propylene copolymers, and polycarbonate oligomeric chains.

As used herein, “(meth)acrylated oligomer” means a polymer molecule having at least two pendent (meth)acryloyl groups and a weight average molecular weight (M_{w}) as determined by Gel Permeation Chromatography of at least 1,000 g/mole and typically less than 50,000 g/mole.

In general higher molecular weight oligomers yield adhesives with better adhesive properties, but are more difficult to coat due to the higher viscosity. When using higher molecular weight oligomers, it is desirable to include a low viscosity diluent monomer.

(Meth)acryloyl epoxy oligomers are multifunctional (meth)acrylate esters and amides of epoxy resins, such as the (meth)acrylated esters of bisphenol-A epoxy resin. Examples of commercially available (meth)acrylated epoxies include those known by the trade designations EBECRYL 600 (bisphenol A epoxy diacrylate of 525 molecular weight), EBECRYL 605 (EBECRYL 600 with 25% tripropylene glycol diacrylate), EBECRYL 3700 (bisphenol-A diacrylate of 524 molecular weight) and EBECRYL 3720H (bisphenol A diacrylate of 524 molecular weight with 20% hexanediol diacrylate) available from Cytec Industries, Inc., Woodland Park, N.J.; and PHOTOMER 3016 (bisphenol A epoxy acrylate), PHOTOMER 3016-40R (epoxy acrylate and 40% tripropylene glycol diacrylate blend), and PHOTOMER 3072 (modified bisphenol A acrylate, etc.) available from BASF Corp., Cincinnati, Ohio, and Ebecryl 3708 (modified bisphenol A epoxy diacrylate) available from Cytec Industries, Inc., Woodland Park, N.J.

(Meth)acrylated urethanes are multifunctional (meth)acrylate esters of hydroxy terminated isocyanate extended polyols, polyesters or polyethers. (Meth)acrylated urethane oligomers can be synthesized, for example, by reacting a diisocyanate or other polyvalent isocyanate compound with a polyvalent polyol (including polyether and polyester polyols) to yield an isocyanate terminated urethane prepolymer. A polyester polyol can be formed by reacting a polybasic acid (e.g., terephthalic acid or maleic acid) with a polyhydric alcohol (e.g., ethylene glycol or 1,6-hexanediol). A polyether polyol useful for making the acrylate functionalized urethane oligomer can be chosen from, for example, polyethylene glycol, polypropylene glycol, poly(tetrahydrofuran), poly(2-methyl-tetrahydrofuran), poly(3-methyl-tetrahydrofuran) and the like. Alternatively, the polyol linkage of an acrylated urethane oligomer can be a polycarbonate polyol.

Subsequently, (meth)acrylates having a hydroxyl group can then be reacted with the terminal isocyanate groups of the prepolymer. Both aromatic and the preferred aliphatic isocyanates can be used to react with the urethane to obtain the oligomer. Examples of diisocyanates useful for making the (meth)acrylated oligomers are 2,4-tolylene diisocyanate, 2,6-tolylene diisocyanate, 1,3-xylylene diisocyanate, 1,4-xylylene diisocyanate, 1,6-hexane diisocyanate, isophorone diisocyanate and the like. Examples of hydroxy terminated acrylates useful for making the acrylated oligomers include, but are not limited to, 2-hydroxyethyl(meth)acrylate, 2-hydroxypropyl(meth)acrylate, α-hydroxybutyl acrylate, polyethylene glycol (meth)acrylate and the like.

A (meth)acrylated urethane oligomer can be, for example, any urethane oligomer having at least two acrylate functionalities and generally less than about six functionalities. Suitable (meth)acrylated urethane oligomers are also commercially available such as, for example, those known by the trade designations PHOTOMER 6008, 6019, 6184 (aliphatic urethane triacrylates) available from Henkel Corp.; EBECRYL 220 (hexafunctional aromatic urethane acrylate of 1000 molecular weight), EBECRYL 284 (aliphatic urethane diacrylate of 1200 molecular weight diluted with 12% of 1,6-hexanediol diacrylate), EBECRYL 4830 (aliphatic urethane diacrylate of 1200 molecular weight diluted with 10% of tetraethylene glycol diacrylate), and EBECRYL 6602 (trifunctional aromatic urethane acrylate of 1300 molecular weight diluted with 40% of trimethylolpropane ethoxy triacrylate), available from UCB Chemical; and SARTOMER CN1963, 963E75, 945A60, 963B80, 968, and 983) available from Sartomer Co., Exton, Pa.

Properties of these materials may be varied depending upon selection of the type of isocyanate, the type of polyol modifier, the reactive functionality and molecular weight. Diisocyanates are widely used in urethane acrylate synthesis and can be divided into aromatic and aliphatic diisocyanates. Aromatic diisocyanates are used for manufacture of aromatic urethane acrylates which have significantly lower cost than aliphatic urethane acrylates but tend to noticeably yellow on white or light colored substrates. Aliphatic urethane acrylates include aliphatic diisocyanates that exhibit slightly more flexibility than aromatic urethane acrylates that include the same functionality, a similar polyol modifier and at similar molecular weight.

The curable composition may comprise a functionalized poly(meth)acrylate oligomer, which may be obtained from the reaction product of: (a) from 50 to 99 parts by weight of (meth)acrylate ester monomer units that are homo- or co-polymerizable to a polymer (b) from 1 to 50 parts by weight of monomer units having a pendent, free-radically polymerizable functional group. Examples of such materials are available from Lucite International (Cordova, Tenn.) under the trade designations of Elvacite 1010, Elvacite 4026, and Elvacite 4059.

The (meth)acrylated poly(meth)acrylate oligomer may comprise a blend of an acrylic or hydrocarbon polymer with multifunctional (meth)acrylate diluents. Suitable polymer/diluent blends include, for example, commercially available products such as EBECRYL 303, 745 and 1710 all of which are available from Cytec Industries, Inc., Woodland Park, N.J.

The curable composition may comprise a (meth)acrylated polybutadiene oligomer, which may be obtained from a carboxyl- or hydroxyl-functionalized polybutadiene. By carboxyl or hydroxy functionalised polybutadiene is meant to designate a polybutadiene comprising free —OH or —COOH groups. Carboxyl functionalized polybutadienes are known, they have for example been described in U.S. Pat. No. 3,705,208 (Nakamuta et al.) and are commercially available under the trade name of Nisso PB C-1000 (Nisso America, New York, N.Y.). Carboxyl functionalized polybutadienes can also be obtained by the reaction of a hydroxyl functionalized polybutadiene (that is a polybutadiene having free hydroxyl groups) with a cyclic anhydride such as for example has been described in U.S. Pat. No. 5,587,433 (Boeckeler), U.S. Pat. No. 4,857,434 (Klinger) and U.S. Pat. No. 5,462,835 (Mirle).

Carboxyl and hydroxyl functionalized polybutadienes suitable for being used in the process according to the present invention contain besides the carboxyl and/or hydroxyl groups, units derived from the polymerization of butadiene. The polybutadiene (PDB) generally comprises 1-4 cis units/1-4 trans units/1-2 units in a ratio a/b/c where a, b and c range from 0 to 1 with a+b+c=1. The number average molecular weight (Mₙ) of the functionalized polybutadiene is preferably from 200 to 10000 Da. The Mₙ is more preferably at least 1000. The Mₙ more preferably does not exceed 5000 Da. The —COOH or —OH functionality is generally from 1.5 to 9, preferably from 1.8 to 6.

Exemplary hydroxyl and carboxyl polybutadienes include without limitation Poly BD R-20LM (hydroxyl functionalized PDB, a=0.2, b=0.6, c=0.2, Mn 1230) and Poly BD R45-HT (hydroxyl functionalized PDB, a=0.2, b=0.6, c=0.2, Mn 2800) commercialized by Atofina, Nisso-PB G-1000 (hydroxyl functionalized PDB, a=0, b<0.15, c>0.85, Mn 1250-1650), Nisso-PB G-2000 (hydroxyl functionalized PDB, a=0, b<0.15, c>0.85, Mn 1800-2200), Nisso-PB G-3000 (hydroxyl functionalized PDB, a=0, b<0.10, c>0.90, Mn 2600-3200), Nisso-PB C-1000 (carboxyl functionalized PDB, a=0, b<0.15, c>0.85, Mn 1200-1550) obtainable from Nisso America, New York, N.Y.

When carboxyl functionalized polybutadienes obtained from the reaction of a hydroxyl functionalized polybutadiene with a cyclic anhydride are used, this cyclic anhydride preferably include phthalic anhydride, hexahydrophthalic anhydride, glutaric anhydride, succinic anhydride, dodecenylsuccinic anhydride, maleic anhydride, trimellitic anhydride, pyromellitic anhydride. Mixtures of anhydrides can also be used. The amount of anhydride used for the preparation of a carboxyl functionalized polybutadiene from a hydroxyl functionalized polybutadiene is generally at least 0.8 molar, preferably at least 0.9 molar and more preferably at least 0.95 molar equivalent per molar equivalents of —OH groups present in the polybutadiene.

A (meth)acrylated polybutadiene oligomer which is the reaction product of a carboxyl functionalized polybutadiene may be prepared with a (meth)acrylated monoepoxide. (Meth)acrylated mono-epoxides are known. Examples of (meth)acrylated mono-epoxides that can be used are glycidyl(meth)acrylate esters, such as glycidylacrylate, glycidylmethacrylate, 4-hydroxybutylacrylate glycidylether, bisphenol-A diglycidylether monoacrylate. The (meth)acrylated mono-epoxides are preferably chosen from glycidylacrylate and glycidylmethacrylate. Alternatively, a (meth)acrylated polybutadiene oligomer which is the reaction product of a hydroxyl functionalized polybutadiene may be prepared with a (meth)acrylate ester, or halide.

Some (meth)acrylated polybutadienes that can be used, for example, include Ricacryl 3100 and Ricacryl 3500, manufactured by Sartomer Company, Exton, Pa., USA, and Nisso TE-2000 available from Nisso America, New York, N.Y. Alternatively, other methacrylated polybutadienes can be used. These include dimethacrylates of liquid polybutadiene resins composed of modified, esterified liquid polybutadiene diols. These are available under the tradename CN301 and CN303, and CN307, manufactured by Sartomer Company, Exton, Pa., USA. Regardless which methacrylated polybutadiene is used with embodiments of the invention, the methacrylated polybutadiene can include a number of methacrylate groups per chain from about 2 to about 20.

Alternatively, the acrylate functionalized oligomers can be polyester acrylate oligomers, acrylated acrylic oligomers, polycarbonate acrylate oligomers or polyether acrylate oligomers. Useful polyester acrylate oligomers include CN293, CN294, and CN2250, 2281, 2900 from Sartomer Co. (Exton, Pa.) and EBECRYL 80, 657, 830, and 1810 from UCB Chemicals (Smyrna, Ga.). Suitable polyether acrylate oligomers include CN501, 502, and 551 from Sartomer Co. (Exton, Pa.). Useful polycarbonate acrylate oligomers can be prepared according to U.S. Pat. No. 6,451,958 (Sartomer Technology Company Inc., Wilmington, Del.).

In each embodiment described herein, the curable composition optionally, yet preferably comprises diluent monomer in an amount sufficient to reduce the viscosity of the curable composition such that it may be coated on a substrate. In particular, it is desirable to reduce the viscosity of the compositions such that it may be spin coated on a substrate. Generally, the composition may comprise up to about 70 wt-% diluent monomers to reduce the viscosity of the oligomeric component to less than 10000 centipoise and to improve the processability.

Useful monomers are desirably soluble or miscible in the (meth)acrylated oligomer, highly polymerizable therewith, and when copolymerized, produce a copolymer having a T_{g} of less than 25° C. Useful diluents are mono- and polyethylenically unsaturated monomers such as (meth)acrylates or (meth)acrylamides. Suitable monomers typically have a number average molecular weight no greater than 450 g/mole. The diluent monomer desirably has minimal absorbance at the wavelength of the radiation used to cure the composition. The T_{g} of the copolymer may be estimated by use of the Fox equation, based on the T_{g}s of the constituent monomers, oligomers, and the weight percent thereof.

Such diluent monomers may include low T_{g} and high T_{g} monomers. Low T_{g} monomers having one ethylenically unsaturated group and a glass transition temperature of the corresponding homopolymer of less than 0° C. which are suitable in the present invention include, for example, n-butyl acrylate, isobutyl acrylate, hexyl acrylate, 2-ethyl-hexylacrylate, isooctylacrylate, caprolactoneacrylate, isodecylacrylate, tridecylacrylate, laurylmethacrylate, methoxy-polyethylenglycol-monomethacrylate, laurylacrylate, tetrahydrofurfuryl-acrylate, ethoxy-ethoxyethyl acrylate and ethoxylated-nonylacrylate. Especially preferred are 2-ethyl-hexylacrylate, ethoxy-ethoxyethyl acrylate, tridecylacrylate and ethoxylated nonylacrylate. High T_{g} monomers having one ethylenically unsaturated group and a glass transition temperature of the corresponding homopolymer of 50° C. or more which are suitable in the present invention, include, for example, N-vinylpyrrolidone, N-vinyl caprolactam, isobornyl acrylate, acryloylmorpholine, isobornylmethacrylate, phenoxyethylacrylate, phenoxyethylmethacrylate, methylmethacrylate and acrylamide.

Furthermore, the diluent monomers may contain an average of two or more free-radically polymerizable groups. A diluent having three or more of such reactive groups can be present as well. Examples of such monomers include: C₂-C₁₈ alkylenedioldi(meth)acrylates, C₃-C₁₈ alkylenetrioltri(meth)acrylates, the polyether analogues thereof, and the like, such as 1,6-hexanedioldi(meth)acrylate, trimethylolpropanetri(meth)acrylate, triethyleneglycoldi(meth)acrylate, pentaeritritoltri(meth)acrylate, and tripropyleneglycol di(meth)acrylate, and di-trimethylolpropane tetraacrylate.

Preferred diluents can have T_{g} of less than 30° C., preferably less than 25° C., when measured as a homopolymer or estimated using the Fox equation. Suitable monomers typically have a number average molecular weight no greater than 450 g/mole. Suitable preferred diluent monomers include for example benzyl(meth)acrylate, phenoxy ethyl(meth)acrylate; phenoxy-2-methylethyl(meth)acrylate; phenoxyethoxyethyl(meth)acrylate, 1-naphthyloxy ethyl acrylate; 2-naphthyloxy ethyl acrylate; phenoxy 2-methylethyl acrylate; phenoxyethoxyethyl acrylate; 2-phenylphenoxy ethyl acrylate; 4-phenylphenoxy ethyl acrylate; and phenyl acrylate.

The inclusion of only one diluent is preferred for ease in manufacturing. Preferred diluent monomers includes phenoxyethyl(meth)acrylate, and benzyl(meth)acrylate. Phenoxyethyl acrylate is commercially available from Sartomer under the trade designation “SR339”; from Eternal Chemical Co. Ltd. under the trade designation “Etermer 210”; and from Toagosei Co. Ltd under the trade designation “TO-1166”. Benzyl acrylate is commercially available from Osaka Organic Chemical, Osaka City, Japan.

Such optional monomer(s) may be present in the polymerizable composition in amount of at least about 5 wt-%. The optional monomer(s) typically total no more than about 70 wt-% of the curable composition. The some embodiments the total amount of diluent monomer ranges from about 10 wt-% to about 50-%.

The curable composition further comprises a perfluoroether monomer. It has been found that the addition of small amounts of such monomers greatly reduces, or eliminates, the bubble or void formation, and persistence thereof, in vacuum lamination operations during wafer processing. The use of the instant adhesives as joining layers in wafer processing is described in detail below, but during the vacuum lamination steps, bubbles are often observed in the joining layer as a vacuum is applied. With the addition of the perfluoroether monomers to the curable adhesive composition, fewer bubbles form, and the majority of those that do form then pop. While not being bound by theory, Applicants believe the monomer may serves as a leveling agent or defoaming agent that is incorporated into the copolymer when cured. However, conventional leveling agents and defoaming agents had no effect on the bubbles.

The instant perfluorinated ether monomers are used in amounts sufficient to reduce the number and persistence of bubbles and voids during wafer processing operations. The monomer is generally used in amounts of at least 0.05 wt. % of the curable components and in amounts of no greater than 1 wt. % of the curable components. Above this amount the composition becomes milky, indicative of incompatibility. Preferably the monomer is used in amounts of 0.1 to 0.5 wt. % of the curable components.

Various perfluoropolyether monomers having ethylenic unsaturations are suitable for use in the polymerization of the perfluoropolyether polymers. Preferred perfluoropolyether monomers can be represented by the following Formula (2):

(R_{f})-(L²-Z²)ₑ (2)

wherein R_{f} is a perfluoropolyether group; L² is a linking group; and Z² is a free-radically polymerizable group such as (meth)acryloyl, vinyl or alkynyl and is preferably a (meth)acrylate; and e is 1 or 2. The perfluoropolyether monomers of formula 2 comprise 0.1 to 2, preferably 0.1 to 1 weight percent of the curable composition.

The perfluoropolyether group R_{f} can be linear, branched, cyclic, or combinations thereof and can be saturated or unsaturated. The perfluoropolyether has at least one catenated (in-chain) oxygen heteroatoms. Exemplary perfluoropolyethers include, but are not limited to, those that have perfluorinated repeating units selected from the group of —(CₚF₂ₚO)—, —(CF(R_{f}¹)O)—, —(CF(R_{f}¹)CₚF₂ₚO)—, —(CₚF₂ₚCF(R_{f}¹)O)—, —(CF₂CF(R_{f}¹)O)—, or combinations thereof. In these repeating units, p is typically an integer of 1 to 10. In some embodiments, p is an integer of 1 to 8, 1 to 6, 1 to 4, or 1 to 3.

The group R_{f}¹ is a fluorine, a perfluoroalkyl group, perfluoroether group, perfluoropolyether, or a perfluoroalkoxy group, all of which can be linear, branched, or cyclic. The R_{f}¹ group typically has no more than 12 carbon atoms, no more than 10 carbon atoms, or no more than 9 carbon atoms, no more than 4 carbon atoms, no more than 3 carbon atoms, no more than 2 carbon atoms, or no more than 1 carbon atom. In some embodiments, the R_{f}¹ group can have no more than 4, no more than 3, no more than 2, no more than 1, or no oxygen atoms. In these perfluoropolyether structures, the different repeat units can be distributed randomly along the chain.

R_{f} can be monovalent (e=1) or divalent (e=2). In some compounds where R_{f} is monovalent, the terminal groups can be (CₚF₂ₚ₊₁)—, (CₚF₂ₚ₊₁O)—, (X′CₚF₂ₚO)—, or (X′CₚF₂ₚ)— where X′ is hydrogen, chlorine, or bromine and p is an integer of 1 to 10. In some embodiments of monovalent R_{f} groups, the terminal group is perfluorinated and p is an integer of 1 to 10, 1 to 8, 1 to 6, 1 to 4, or 1 to 3. Exemplary monovalent R_{f} groups include CF₃O(C₂F₄O)ₐCF₂—, C₃F₇O(CF₂CF₂CF₂O)ₐCF₂CF₂—, and C₃F₇O(CF(CF₃)CF₂O)ₐCF(CF₃)— wherein “a” has an average value of 0 to 50, 1 to 50, 3 to 30, 3 to 15, or 3 to 10.

Suitable structures for divalent R_{f} groups include, but are not limited to, —CF₂O(CF₂O)_{b}(C₂F₄O)ₐCF₂—, —CF₂CF₂O(C₃F₆O)ₐCF₂CF₂—, —(CF₂)₃O(C₄F₈O)ₐ(CF₂)₃—, —CF₂O(C₂F₄O)ₐCF₂—, and —CF(CF₃)(OCF₂CF(CF₃))_{b}OC₁F₂ₜO(CF(CF₃)CF₂O)ₐCF(CF₃)—, wherein a and b independently average value of 0 to 50, 1 to 50, 3 to 30, 3 to 15, or 3 to 10; the sum (a+b) has an average value of 0 to 50 or 4 to 40; and t is an integer of 2 to 6.

As synthesized, compounds according to Formula (1) typically include a mixture of R_{f} groups. The average structure is the structure averaged over the mixture components. The values of a, b and t in these average structures can vary, as long as the compound has a number average molecular weight of at least about 600. Compounds of Formula (1) preferably have a molecular weight (number average) of 700, 800, 900, 1,000, 1100, 1200, 1300, 1400, 1500, 1600, 1700, 1800, 1900, or 2000 and no greater than about, 5,000, 4,000, or 3,000.

The linking group L² between the perfluoropolyether segment and ethylenically unsaturated end group is a (hetero)hydrocarbyl group and includes a divalent or higher valency group selected from an alkylene, arylene, heteroalkylene, or combinations thereof and an optional divalent functional group selected from ether, thioether, carbonyl, ester, amide, urea, urethane, sulfonamide, or combinations thereof. L² can be unsubstituted or substituted with an alkyl, aryl, halo, or combinations thereof. The L² group typically has no more than 30 carbon atoms. In some compounds, the L² group has no more than 20 carbon atoms, no more than 10 carbon atoms, no more than 6 carbon atoms, or no more than 4 carbon atoms. For example, L² can be an alkylene, an alkylene substituted with an aryl group, or an alkylene in combination with an arylene or an alkyl ether or alkyl thioether linking group.

Perfluoropolyether acrylate compounds can be synthesized by known techniques such as described in U.S. Pat. Nos. 3,553,179 and 3,544,537 as well as U.S. Pat. No. 7,094,829 (Dams)

The perfluoropolyether (meth)acrylate compound may be produced by introducing (meth)acryl group at the terminal hydroxyl group or amine group of perfluoropolyether compound. Suitable examples of such terminal hydroxyl-group containing fluoropolyether compounds includes for example:

HOCH₂—CF₂O—[CF₂CF₂O]ₐ—[CF₂O]_{b}—CF₂CH₂OH,
F—[CF₂CF₂CF₂O]ₐ—CF₂CF₂CH₂OH,
F—[CF(CF₃)CF₂O]ₐ—CF(CF₃)CH₂OH,
HO(CH₂CH₂O)ₙ—CH₂—CF₂O—[CF₂CF₂O]ₐ—[CF₂O]_{b}—CF₂CH₂(OCH₂CH₂)ₙOH, and
HOCH₂CH(OH)CH₂O—CH₂—CF₂O—[CF₂CF—₂O]ₐ—[CF₂O]_{b}—CF₂CH₂OCH₂CH(OH)CH₂OH, wherein a and b independently average value of 0 to 50, 1 to 50, 3 to 30, 3 to 15, or 3 to 10; the sum (a+b) has an average value of 1 to 50 or 4 to 40; and n is an integer of 0 to 6, preferably 1 to 6. It will be apparent to one skilled in the art that the illustrated hydroxyl groups may be substituted with other nucleophilic groups, such as amino groups.

In some embodiments, the perfluoropolyether group comprises an “HFPO—” end group, i.e. the end group F(CF(CF₃)CF₂O)ₐCF(CF₃)— (of the methyl ester F(CF(CF₃)CF₂O)ₐCF(CF₃)C(O)OCH₃) wherein “a” averages 2 to 15. In some embodiments, “a” averages at least 3 or 4. Typically, “a” is generally no greater than 10. Such compound generally exist as a distribution or mixture of oligomers with a range of values for a, so that the average value of a may be non-integer.

In addition to the curable oligomer, optional diluent and the perfluorinated ether, the curable composition further comprises photoinitiators, in an amount between the range of about 0.1% and about 5% by weight.

Useful photoinitiators include those known as useful for photocuring free-radically polyfunctional (meth)acrylates. Exemplary photoinitiators include benzoin and its derivatives such as alpha-methylbenzoin; alpha-phenylbenzoin; alpha-allylbenzoin; alpha-benzylbenzoin; benzoin ethers such as benzil dimethyl ketal (e.g., “IRGACURE 651” from BASF, Florham Park, N.J.), benzoin methyl ether, benzoin ethyl ether, benzoin n-butyl ether; acetophenone and its derivatives such as 2-hydroxy-2-methyl-1-phenyl-1-propanone (e.g., “DAROCUR 1173” from BASF, Florham Park, N.J.) and 1-hydroxycyclohexyl phenyl ketone (e.g., “IRGACURE 184” from BASF, Florham Park, N.J.); 2-methyl-1-[4-(methylthio)phenyl]-2-(4-morpholinyl)-1-propanone (e.g., “IRGACURE 907” from BASF, Florham Park, N.J.); 2-benzyl-2-(dimethylamino)-1-[4-(4-morpholinyl)phenyl]-1-butanone (e.g., “IRGACURE 369” from BASF, Florham Park, N.J.) and phosphine oxide derivatives such as Ethyl-2,4,6-trimethylbenzoylphenylphoshinate (e.g. “TPO-L” from BASF, Florham Park, N.J.), and Irgacure 819 (phenylbis(2,4,6-trimethylbenzoyl)phosphine oxide) available from BASF, Florham Park, N.J.

Other useful photoinitiators include, for example, pivaloin ethyl ether, anisoin ethyl ether, anthraquinones (e.g., anthraquinone, 2-ethylanthraquinone, 1-chloroanthraquinone, 1,4-dimethylanthraquinone, 1-methoxyanthraquinone, or benzanthraquinone), halomethyltriazines, benzophenone and its derivatives, iodonium salts and sulfonium salts, titanium complexes such as bis(eta₅-2,4-cyclopentadien-1-yl)-bis[2,6-difluoro-3-(1H-pyrrol-1-yl)phenyl]titanium (e.g., “CGI 784DC” from BASF, Florham Park, N.J.); halomethyl-nitrobenzenes (e.g., 4-bromomethylnitrobenzene), mono- and bis-acylphosphines (e.g., “IRGACURE 1700”, “IRGACURE 1800”, “IRGACURE 1850”, and “DAROCUR 4265”).

The curable composition may be irradiated with activating UV or visible radiation to polymerize the components preferably in the wavelengths of 250 to 500 nanometers. UV light sources can be of two types: 1) relatively low light intensity sources such as blacklights that provide generally 10 mW/cm² or less (as measured in accordance with procedures approved by the United States National Institute of Standards and Technology as, for example, with a UVIMAP™ UM 365 L-S radiometer manufactured by Electronic Instrumentation & Technology, Inc., in Sterling, Va.) over a wavelength range of 280 to 400 nanometers and 2) relatively high light intensity sources such as medium- and high-pressure mercury arc lamps, electrodeless mercury lamps, light emitting diodes, mercury-xenon lamps, lasers and the like, which provide intensities generally between 10 and 5000 mW/cm² in the wavelength rages of 320-390 nm (as measured in accordance with procedures approved by the United States National Institute of Standards and Technology as, for example, with a PowerPuck™ radiometer manufactured by Electronic Instrumentation & Technology, Inc., in Sterling, Va.).

When photopolymerizing the curable composition, it is expedient for the photoinitiated polymerization reactions to proceed to virtual completion, i.e., depletion of the monomeric components, at temperatures less than about 70° C. (preferably at 50° C. or less) with reaction times less than 1 hour, preferably less than 10 minutes, and more preferably less than 2 minutes. The cured composition may be represented by the following simplified formula showing the polymerized monomer units from the perfluoropolyether monomer comprising “x” weight percent, the oligomer component comprising “y”, and the optional diluent monomer (R^{dil}) comprising “z” weight percent, corresponding to the weight percents previously described. It will be apparent that the monomer units may comprise addition polymerizable groups Z¹ and Z² that are available for further polymerization and/or crosslinking. Further the optional diluent monomer may have additional polymerizable groups.

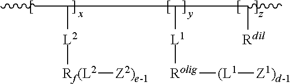

Adhesive articles may be prepared by coating, either before or after curing, the adhesive composition on a suitable support, such as a flexible backing Examples of materials that can be included in the flexible backing include polyolefins such as polyethylene, polypropylene (including isotactic polypropylene), polystyrene, polyester, polyvinyl alcohol, poly(ethylene terephthalate), poly(butylene terephthalate), poly(caprolactam), poly(vinylidene fluoride), polylactides, cellulose acetate, and ethyl cellulose and the like. Commercially available backing materials useful in the invention include kraft paper; cellophane; spun-bond poly(ethylene) and poly(propylene), such as Tyvek™ and Typar™ (available from DuPont, Inc.); and porous films obtained from poly(ethylene) and poly(propylene), such as Teslin™ (available from PPG Industries, Inc.), and Cellguard™ (available from Hoechst-Celanese).

Backings may also be prepared of fabric such as woven fabric formed of threads of synthetic or natural materials such as cotton, nylon, rayon, glass, ceramic materials, and the like or nonwoven fabric such as air laid webs of natural or synthetic fibers or blends of these. The backing may also be formed of metal, metallized polymer films, or ceramic sheet materials may take the form of any article conventionally known to be utilized with adhesive compositions such as labels, tapes, signs, covers, marking indicia, and the like.

The above-described compositions are coated on a substrate using conventional coating techniques modified as appropriate to the particular substrate. For example, these compositions can be applied to a variety of solid substrates by methods such as roller coating, flow coating, dip coating, spin coating, spray coating knife coating, and die coating. These various methods of coating allow the compositions to be placed on the substrate at variable thicknesses thus allowing a wider range of use of the compositions.

Coating thicknesses may vary as previously described. The solutions may be of any desirable concentration, and degree of conversion, for subsequent coating, but is typically between 20 to 70 wt. % polymer solids, and more typically between 30 and 50 wt. % solids, in solvent. The desired concentration may be achieved by further dilution of the coating composition, or by partial drying.

The flexible support may also comprise a release-coated substrate. Such substrates are typically employed when an adhesive transfer tape is provided. Examples of release-coated substrates are well known in the art and include, by way of example, silicone-coated kraft paper and the like. Tapes of the invention may also incorporate a low adhesion backsize (LAB) which are known in the art.

In some embodiments substrates to which the coating compositions of the invention can be applied are transmissive; i.e. transparent or translucent to visible light. In some embodiments the substrate is selected to be transmissive at the wavelength used to initiate photopolymerization. Preferred substrates are made of polyester (e.g., polyethylene terephthalate, polybutyleneterephthalate), polycarbonate, allyldiglycolcarbonate, polyacrylates, such as polymethylmethacrylate, polystyrene, polysulfone, polyethersulfone, homo-epoxy polymers, epoxy addition polymers with polydiamines, polydithiols, polyethylene copolymers, fluorinated surfaces, cellulose esters such as acetate and butyrate, glass, ceramic, organic and inorganic composite surfaces and the like, including blends and laminates thereof.

In one embodiment, the present adhesive composition is useful as a joining layer in the field of wafer processing. Wafer support systems (WSS) are used in the field of wafer planarization to temporarily bond wafers, such as silicon wafers, to a rigid carrier in order to grind the back surfaces of the wafers to a desired thickness. One method currently used for temporarily supporting a wafer is the Wafer Support System (WSS) for ultra thin wafer back-grinding developed by 3M Company located in St. Paul, Minn. This technique utilizes a carrier, such as a glass carrier, having a photothermal conversion layer coated on the carrier. The carrier is positioned on the wafer such that, when the carrier and wafer are laminated together, the photothermal conversion layer is positioned between the carrier and the wafer.

An ultraviolet (UV) curable joining layer is spin-coated onto the wafer such that the photothermal conversion layer is actually in contact with the joining layer. The photothermal conversion layer and the joining layer thus temporarily bond the wafer to the carrier during grinding operations and subsequent processing steps. After the grinding operations and wafer processing steps are completed, the wafer and joining layer are de-bonded from the carrier by applying radiation energy to the photothermal conversion layer. The application of the radiation energy causes the photothermal conversion layer to decompose, allowing separation of the carrier from the joining layer and the substrate.

After the joining layer is deposited onto the wafer, the space between the wafer and the carrier is evacuated and the carrier is moved into contact with the liquid joining layer. If the topography on the surface of the wafer is small enough, the joining layer can flow and fill in any spaces between features. However, if the topography of the surface of the wafer is too large, the joining layer cannot flow enough to fill all the spaces between features and, as a consequence, voids remain after bonding. Voids may also be present if there are large spaces between features on the wafer surface.

It is desired to eliminate voids between the wafer and the carrier because subsequent backside processing steps are often performed at high temperatures. At high temperatures, the pressure within the voids can increase, causing the wafer to delaminate from the carrier. The ability to bond wafers with large topographies is important because an increasing number of process flows require bonding wafer surfaces that have solder balls, pre-bonded die or other large features already in place. The instant adhesive compositions overcome problems in the art, reducing or eliminating void formation in water processing.

When used in processing wafers with large topographies, the present disclosure provides an article that includes a substrate, an optional leveling layer, a joining layer comprising the instant adhesive, a photothermal conversion layer and a carrier. The substrate has a first major surface, a second major surface and at least one three dimensional topographical feature extending from the first major surface and having an initial step height. The leveling layer is positioned adjacent to the first major surface and reduces a topography of the substrate to between about 5% and about 95% of the initial step height. The joining layer is positioned adjacent to the leveling layer and further reduces the topography of the substrate to less than about 20% of the initial step height. The photothermal conversion layer is positioned adjacent to the joining layer and the temporary carrier is positioned adjacent the photothermal conversion layer.

In a second embodiment, the present invention is a method of manufacturing a laminated article. The method includes providing a substrate having first and second major surfaces, wherein at least the first major surface includes a three dimensional topographical feature covering at least a portion of its surface, the topographical feature having an initial step height; coating a leveling layer on the first major surface to reduce the topography of the substrate; coating a joining layer comprising the instant adhesive composition onto the leveling layer to further reduce the topography of the substrate; providing a temporary carrier; providing a photothermal conversion layer; joining the substrate to the carrier; and drying or curing the photothermal conversion layer, joining layer and an optional leveling layer to form the laminated article. The leveling layer reduces the topography of the substrate to between about 5% and about 95% of the initial step height. The joining layer reduces the topography of the substrate to less than about 20% of the initial step height. The substrate is joined to the temporary carrier by contacting the joining layer to the photothermal conversion layer and the photothermal conversion layer to the temporary carrier.

The present disclosure provides a layered body in which a substrate to be ground is fixed on a support, by means of the instant adhesive joining layer, and the joining layer can be easily peeled off from the substrate after grinding and processing steps that require elevated temperatures. The present disclosure further provides a method for manufacturing the layered body and a method for manufacturing a thin substrate using the layered body. In some preferred embodiments, the thin substrate may comprise a semiconductor wafer.

In one embodiment of the present disclosure, a layered body is provided. The layered body comprises a substrate to be ground; a joining layer comprising a curable acrylate polymer and a curable acrylate adhesion modifying agent in contact with the substrate to be ground; a photothermal conversion layer comprising a light absorbing agent and a heat decomposable resin; and a light transmitting carrier. After grinding the substrate surface that is opposite the surface that is in contact with the joining layer, the layered body can be irradiated through the light-transmitting support to decompose the photothermal conversion layer and to separate the substrate and the light transmitting carrier. In this layered body, the substrate that has been ground to a very small thickness can be separated from the support without breaking the substrate.

A method for manufacturing the above-described layered body is also provided. The method comprises the steps of: providing a photothermal conversion layer on a light transmitting carrier, applying a joining layer to a substrate to be ground or to the photothermal conversion layer, joining the substrate to be ground and the photothermal conversion layer by means of the joining layer, under reduced pressure, and curing the joining layer to form a layered body. The photothermal conversion layer may be provided by providing a photothermal conversion layer precursor containing a light absorbing agent and a heat decomposable resin solution, or a monomer or oligomer as a precursor material of a heat decomposable resin; and drying to solidify or cure the photothermal conversion layer precursor to form a photothermal conversion layer on the light transmitting carrier.

By joining the substrate to be ground and the light transmitting carrier through the joining layer under reduced pressure, bubbles and dust contamination are prevented from forming inside the layered body, so that a level surface can be formed and the substrate can maintain the evenness of thickness after grinding.

In still another embodiment of the present disclosure, a method for manufacturing a reduced thickness substrate is provided. The method comprises the steps of preparing the above-described layered body, grinding the substrate to a desired thickness, irradiating the photothermal conversion layer through the light transmitting carrier to decompose the photothermal conversion layer and thereby to separate the substrate from the light transmitting carrier after grinding, and peeling the joining layer from the substrate after grinding. In this method, a substrate can be ground to a desired thickness (for example, 150 μm or less, preferably 50 μm or less, more preferably 25 μm or less) on a support. After grinding and additional processes carried out at elevated temperature, the carrier is separated from the substrate using exposure to radiation energy, so that the joining layer remaining on the substrate after grinding can be easily peeled from the substrate.

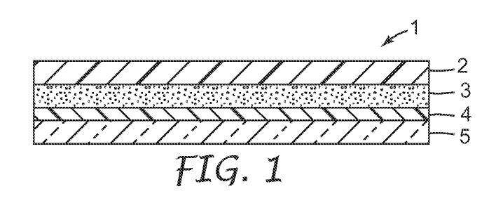

The layered body features a cured acrylated oligomeric adhesive joining layer for joining the substrate to be ground to a support. In the layered body 1 of FIG. 1, a substrate 2 to be ground, a joining layer 3, a photothermal conversion layer 4 and a carrier 5 are shown. The elements comprising the layered body of the present disclosure are described in greater detail below.

The joining layer is used for fixing the substrate to be ground to the carrier through a photothermal conversion layer. The joining layer comprises the instant curable composition. In another embodiment, the joining layer comprises a curable acrylate polymer and a curable acrylate adhesion modifying agent. After the separation of the substrate and the carrier by the decomposition of the photothermal conversion layer, a substrate having the joining layer thereon is obtained. The joining layer may be separated easily from the substrate, such as by peeling. Thus, the joining layer has adhesion strength high enough to fix the substrate to the carrier yet low enough to permit separation from the substrate even after being exposed to high temperature for extended periods.

In addition to the curable oligomer, the joining layer optionally includes a curable acrylate adhesion modifying agent. The joining layer can include a curable acrylate adhesion modifying agent in an amount greater than about 0.1% or an amount less than about 7.0% by weight. The curable acrylate adhesion modifying agent can be silicone polymers substituted with at least one of acrylate group(s) or methacrylate group(s). Preferably the curable acrylate adhesion modifying agent is soluble in the curable acrylate polymer before curing. In addition, it is preferable that the viscosity of the combination of the curable acrylate adhesion modifying agent and the curable acrylate polymer be less than about 10,000 centipoise at ambient temperature and more preferably less than 5,000 centipoise. For example, the curable acrylate adhesion modifying agent may be an acrylate modified silicone polymer, such as Ebecryl 350 from Cytec Industries (West Paterson, N.J.), CN9800 from Sartomer Company (Exton, Pa.) or Tego Rad 2250, Tego Rad 2500, Tego Rad 2650 and Tego Rad 2700 from Evonik Industries (Essen, Germany).

The curable adhesive joining layer may further comprise photoinitiators, in an amount between the range of about 0.1% and about 5% by weight. Useful photoinitiators include those described supra.

The substrate to be ground, such as a silicon wafer, generally has asperities such as circuit patterns on one side. For the joining layer to fill in the asperities of the substrate to be ground and rendering the thickness of the joining layer uniform, the adhesive used for the joining layer is preferably in a liquid state during coating and layering and preferably has a viscosity of less than 10,000 centipoise (cps) at the temperature (for example, 25° C.) of the coating and layering operations. This liquid acrylate adhesive is preferably coated by a spin coating method among various methods known in the art. As such an adhesive, a UV-curable or a visible light-curable adhesive are particularly preferred, because the thickness of the joining layer can be made uniform and moreover, the processing speed is high.

The thickness of the joining layer is not particularly limited as long as it can ensure the thickness uniformity required for the grinding of the substrate to be ground and the tear strength necessary for the peeling of the joining layer from the wafer after removing the carrier from the layered body, and can sufficiently absorb the asperities on the substrate surface. The thickness of the joining layer is typically from about 10 to about 250 μm, preferably from about 25 to about 150 μm. Prior to assembling the layered body, if desired, the substrate may be partially sawn through on the face adjacent the joining layer (circuit face).

The substrate may be, for example, a brittle material difficult to thin by conventional methods. Examples thereof include semiconductor wafers such as silicon and gallium arsenide, a rock crystal wafer, sapphire and glass.

The light transmitting carrier is a material capable of transmitting radiation energy, such as a laser beam used in the present disclosure, and the material is required to keep the ground body in a flat state and not cause it to break during grinding and conveyance. The light transmittance of the carrier is not limited as long as it does not prevent the transmittance of a practical intensity level of radiation energy into the photothermal conversion layer to enable the decomposition of the photothermal conversion layer. However, the transmittance is preferably, for example, 50% or more. Also, in order to prevent the ground body from warping during grinding, the light transmitting carrier preferably has a sufficiently high stiffness and the flexural rigidity of the carrier is preferably 2×10⁻³ (Pa·m³) or more, more preferably 3×10⁻² (Pa·m³) or more. Examples of useful carriers include glass plates and acrylic plates. Furthermore, in order to enhance the adhesive strength to an adjacent layer such as photothermal conversion layer, the carrier may be surface-treated with a silane coupling agent or the like, if desired. In the case of using a UV-curable photothermal conversion layer or joining layer, the carrier preferably transmits ultraviolet radiation.

The carrier is sometimes exposed to heat generated in the photothermal conversion layer when the photothermal conversion layer is irradiated or when a high temperature is produced due to frictional heating during grinding. Also, for the purpose of forming a metal film on the substrate a process such as vapor deposition or plating may be additionally provided before separating the ground substrate from the carrier. In addition, a dry etching process may be provided to form vias in the substrate. Particularly, in the case of a silicon wafer, the carrier is sometimes subjected to a high-temperature process to form an oxide film. Accordingly, a carrier having heat resistance, chemical resistance and a low expansion coefficient is selected. Examples of carrier materials having these properties include borosilicate glass available as Pyrex™ and Tempax™ and alkaline earth boro-aluminosilicate glass such as Corning™ #1737 and #7059.

To obtain the desired thickness uniformity after grinding of the substrate, the thickness of the carrier is preferably uniform. For example, for grinding a silicon wafer to 50 μm or less and attaining evenness of ±10% or less, the variability in the thickness of the carrier should be reduced to ±2 μm or less. In the case where the carrier is repeatedly used, the carrier also preferably has scratch resistance. For repeatedly using the carrier, the wavelength of the radiation energy and the carrier may be selected to suppress the damage to the carrier by the radiation energy. For example, when Pyrex glass is used as the carrier and a third harmonic generation YAG laser (355 nm) is employed, the separation of the support and the substrate can be performed, however, such a support exhibits low transmittance at the wavelength of this laser and absorbs the radiation energy, as a result, the support is thermally damaged and cannot be reused in some cases.

The photothermal conversion layer contains a light absorbing agent and a heat decomposable resin. Radiation energy applied to the photothermal conversion layer in the form of a laser beam or the like is absorbed by the light absorbing agent and converted into heat energy. The heat energy generated abruptly elevates the temperature of the photothermal conversion layer and the temperature reaches the thermal decomposition temperature of the heat decomposable resin (organic component) in the photothermal conversion layer resulting in decomposition of the resin. The gas generated by the decomposition is believed to form a void layer (such as air space) in the photothermal conversion layer and divide the photothermal conversion layer into two parts, whereby the carrier and the substrate are separated.

The light-absorbing agent absorbs radiation energy at the wavelength used. The radiation energy is usually a laser beam having a wavelength of 300 to 11,000 nanometers (nm), preferably 300 to 2,000 nm and specific examples thereof include a YAG laser which emits light at a wavelength of 1,064 nm, a second harmonic generation YAG laser at a wavelength of 532 nm, and a semiconductor laser at a wavelength of 780 to 1,300 nm. Although the light absorbing agent varies depending on the wavelength of the laser beam, examples of the light absorbing agent which can be used include carbon black, graphite powder, microparticle metal powders such as iron, aluminum, copper, nickel, cobalt, manganese, chromium, zinc and tellurium, metal oxide powders such as black titanium oxide, and dyes and pigments such as an aromatic diamino-based metal complex, an aliphatic diamine-based metal complex, an aromatic dithiol-base metal complex, a mercaptophenol-based metal complex, a squarylium-based compound, a cyanine-based dye, a methine-based dye, a naphthoquinone-based dye and an anthraquinone-based dye. The light-absorbing agent may be in the form of a film including a vapor deposited metal film. Among these light-absorbing agents, carbon black is particularly useful, because the carbon black significantly decreases the force necessary for separating the substrate from the support after the irradiation and accelerates the separation.

The concentration of the light-absorbing agent in the photothermal conversion layer varies depending on the kind, particle state (structure) and dispersion degree of the light absorbing agent but the concentration is usually from 5 to 70 vol. % in the case of general carbon black having a particle size of approximately from 5 to 500 nm. If the concentration is less than 5 vol. %, heat generation of the photothermal conversion layer may be insufficient for the decomposition of the heat decomposable resin, whereas if it exceeds 70 vol. %, the photothermal conversion layer becomes poor in the film-forming property and may readily cause failure of adhesion to other layers. In the case where the adhesive used as the joining layer is a UV-curable adhesive, if the amount of carbon black is excessively large, the transmittance of the ultraviolet ray through the photothermal conversion layer for curing the adhesive decreases. Therefore, in the case of using a UV-curable acrylate adhesive as the joining layer, the amount of carbon black should be 60 vol. % or less. In order to reduce the force at the time of removing the carrier after irradiation and thereby prevent abrasion of the photothermal conversion layer during grinding (such as abrasion due to abrasive in wash water), carbon black is preferably contained in the photothermal conversion layer in an amount of 20 to 60 vol. %, more preferably from 35 to 55 vol. %.

Examples of the heat decomposable resin which can be used include gelatin, cellulose, cellulose ester (e.g., cellulose acetate, nitrocellulose), polyphenol, polyvinyl butyral, polyvinyl acetal, polycarbonate, polyurethane, polyester, polyorthoester, polyacetal, polyvinyl alcohol, polyvinylpyrrolidone, a copolymer of vinylidene chloride and acrylonitrile, poly(meth)acrylate, polyvinyl chloride, silicone resin and a block copolymer comprising a polyurethane unit. These resins can be used individually or in combination of two or more thereof. The glass transition temperature (T_{g}) of the resin is preferably room temperature (20° C.) or more so as to prevent the re-adhesion of the photothermal conversion layer once it is separated due to the formation of a void layer as a result of the thermal decomposition of the heat decomposable resin, and the T_{g} is more preferably 100° C. or more so as to prevent the re-adhesion. In the case where the light transmitting carrier is glass, in order to increase the adhesive force between the glass and the photothermal conversion layer, a heat decomposable resin having within the molecule a polar group (e.g., —COOH, —OH) capable of hydrogen-bonding to the silanol group on the glass surface can be used. Furthermore, in applications requiring a chemical solution treatment such as chemical etching, in order to impart chemical resistance to the photothermal conversion layer, a heat decomposable resin having within the molecule a functional group capable of self-crosslinking upon heat treatment, a heat decomposable resin capable of being crosslinked by ultraviolet or visible light, or a precursor thereof (e.g., a mixture of monomers and/or oligomers) may be used. For forming the photothermal conversion layer as an adhesive photothermal conversion layer as shown in FIG. 1, an adhesive polymer formed from poly(meth)acrylate or the like, may be used for the heat decomposable resin.

The photothermal conversion layer may contain a transparent filler, if desired. The transparent filler acts to prevent the re-adhesion of the photothermal conversion layer once it is separated due to the formation of a void layer as a result of the thermal decomposition of the heat decomposable resin. Therefore, the force required for the separation of the substrate and the carrier, after grinding of the substrate and subsequent irradiation, can be further reduced. Furthermore, since the re-adhesion can be prevented, the latitude in the selection of the heat decomposable resin is broadened. Examples of the transparent filler include silica, talc and barium sulfate. Use of the transparent filler is particularly advantageous when a UV or visible-curable adhesive is used as the joining layer. Further information regarding the use of transparent fillers may be had with reference to U.S. Pat. No. 7,534,498 (Noda et al.), incorporated herein by reference, and U.S. Pat. No. 7,452,752 (Noda et al.).

The photothermal conversion layer may contain other additives, if desired. For example, in the case of forming the layer by coating a heat decomposable resin in the form of a monomer or an oligomer and thereafter polymerizing or curing the resin, the layer may contain a photo-polymerization initiator. Also, the addition of a coupling agent (integral blend method, i.e., the coupling agent is used as an additive in the formulation rather than as a pre-surface-treatment agent) for increasing the adhesive force between the glass and the photothermal conversion layer, and the addition of a crosslinking agent for improving the chemical resistance are effective for their respective purposes. Furthermore, in order to promote the separation by the decomposition of the photothermal conversion layer, a low-temperature gas generator may be contained. Representative examples of the low-temperature gas generator that can be used include a foaming agent and a sublimating agent. Examples of the foaming agent include sodium hydrogencarbonate, ammonium carbonate, ammonium hydrogencarbonate, zinc carbonate, azodicarbonamide, azobisisobutylonitrile, N,N′-dinitrosopentamethylenetetramine, p-toluenesulfonylhydrazine and p,p-oxybis(benzenesulfonylhydrazide). Examples of the sublimating agent include 2-diazo-5,5-dimethylcyclohexane-1,3-dione, camphor, naphthalene, borneol, butyramide, valeramide, 4-tert-butylphenol, furan-2-carboxylic acid, succinic anhydride, 1-adamantanol and 2-adamantanone.

The photothermal conversion layer can be formed by mixing the light absorbing agent such as carbon black, the heat decomposable resin and a solvent to prepare a precursor coating solution, coating this solution on the carrier, and drying it. Also, the photothermal conversion layer can be formed by mixing the light absorbing agent, a monomer or an oligomer as a precursor material for the heat decomposable resin and, optionally, additives such as photo-polymerization initiator, and a solvent, if desired, to prepare a precursor coating solution in place of the heat decomposable resin solution, coating the solution on the carrier, drying and polymerizing/curing it. For the coating, a general coating method suitable for coating on a hard substrate, such as spin coating, die coating, and roll coating, can be used.

In general, the thickness of the photothermal conversion layer is not limited as long as it permits the separation of the carrier and the substrate, but it is usually 0.1 μm or more. If the thickness is less than 0.1 μm, the concentration of the light-absorbing agent required for sufficient light absorption becomes high and this deteriorates the film-forming property, and as a result, adhesion to the adjacent layer may fail. On the other hand, if the thickness of the photothermal conversion layer is 5 μm or more while keeping constant the concentration of the light-absorbing agent required permitting the separation by the thermal decomposition of the photothermal conversion layer, the light transmittance of the photothermal conversion layer (or a precursor thereof) becomes low. As a result, when a photo-curable, for example, an ultraviolet (UV)-curable photothermal conversion layer, and a joining layer are used, the curing process is sometimes inhibited to the extent that a sufficiently cured product cannot be obtained. Therefore, in the case where the photothermal conversion layer is, for example, ultraviolet-curable, in order to minimize the force required to separate the substrate from the carrier after irradiation and to prevent the abrasion of the photothermal conversion layer during grinding, the thickness of the photothermal conversion layer is preferably from about 0.3 to about 3 μm, more preferably from about 0.5 to about 2.0 μm.

Since the substrate to be ground of the layered body of the present disclosure can be a wafer having formed thereon a circuit, the wafer circuit may be damaged by radiation energy such as a laser beam reaching the wafer through the light transmitting support, the photothermal conversion layer and the joining layer. To avoid such circuit damage, a light absorbing dye capable of absorbing light at the wavelength of the radiation energy or a light reflecting pigment capable of reflecting the light may be contained in any of the layers constituting the layered body or may be contained in a layer separately provided between the photothermal conversion layer and the wafer. Examples of light absorbing dyes include dyes having an absorption peak in the vicinity of the wavelength of the laser beam used (for example, phthalocyanine-based dyes and cyanine-based dyes). Examples of light reflecting pigments include inorganic white pigments such as titanium oxide.

The layered body of the present disclosure (shown in FIG. 1) may comprise additional layers other than the substrate to be ground, the joining layer in contact with the substrate to be ground, the photothermal conversion layer and the light transmitting carrier. Examples of the additional layer include a first intermediate layer (not shown) between the joining layer 3 and the photothermal conversion layer 4, and/or a second intermediate layer (not shown) provided between the photothermal conversion layer 4 and the carrier 5. The second intermediate layer is preferably joined to the carrier 5 through a joining layer 3.

In the case where the first intermediate layer is provided, the layered body 1 is separated at the photothermal conversion layer 4 after the irradiation and a layered body of first intermediate layer/joining layer 3/substrate 2 is obtained. Therefore, the first intermediate layer acts as a backing during the separation of the joining layer 3 from substrate 2 and enables the easy separation of the two. The first intermediate layer is preferably a multilayer optical film. Also, the first intermediate layer is preferably a film which selectively reflects the radiation energy used to enable the separation, such as YAG laser (near infrared wavelength light). This film is preferred because when the first intermediate layer does not transmit but reflects radiation energy, the radiation energy is prevented from reaching the wafer surface, where circuitry is present, and this eliminates the possibility of damage to the circuitry.

In the case of using a photocurable acrylate adhesive as the joining layer 3, a film having a sufficiently high transmittance for curing light such as ultraviolet light is preferred. Accordingly, the multilayer optical film is preferably transmissive to ultraviolet light and selectively reflects near infrared light. The preferred multilayer optical film which is transmissive to ultraviolet light and reflects near infrared light is available as 3M™ Solar Reflecting Film (3M Company, St. Paul, Minn.). The first intermediate layer functions as a substrate for the removal of joining layer 3 from substrate 2 by peeling and therefore, preferably has a thickness of 20 μm or more, more preferably 30 μm or more, and a breaking strength of 20 MPa or more, more preferably 30 MPa or more, still more preferably 50 MPa or more.

In the case where the above-described second intermediate layer is provided, a layered body of second intermediate layer/joining layer 3/light transmitting carrier 5 is obtained after the irradiation of the layered body 1. Therefore, the second intermediate layer acts as a backing during the separation of the joining layer 3 and carrier 5 and enables the easy separation of the two. As such, by providing a second intermediate layer, the photothermal conversion layer 4 or the joining layer 3 (curable acrylate adhesive) is prevented from remaining on the light transmitting carrier 5, and the carrier 5 can be easily recycled. In order to enable the removal of joining layer 3 from carrier 5 by peeling them apart after the laser irradiation and without rupturing, the second intermediate layer preferably has a thickness of 20 μm or more, more preferably 30 μm or more, and a breaking strength of 20 MPa or more, more preferably 30 MPa or more, still more preferably 50 MPa or more. In some cases, the resin of the second intermediate layer permeates into the photothermal conversion layer 4, such as when the second intermediate layer is coated as a mixture of photocurable oligomer and monomer and cured with UV (e.g., when the sheet is produced by coating photothermal conversion layer on the film substrate, coating the second intermediate layer on photothermal conversion layer and curing it, and coating the joining layer on the second intermediate layer). In such cases, in order to prevent re-adhering of the surface separated with a space formed by the laser irradiation, the T_{g} of the resin of the second intermediate layer (in the case of a photocurable resin, the T_{g} of the cured resin) may be 40° C. or more.

In the manufacture of the layered body, it is important to prevent undesirable foreign substances such as air from entering between layers. For example, if air enters between layers, the thickness uniformity of the layered body is prevented and the substrate to be ground cannot be ground to a thin substrate. In the case of manufacturing a layered body 1 shown in FIG. 1, the following method, for example, may be considered. First, the precursor coating solution of the photothermal conversion layer 4 is coated on the carrier 5 by any one of the methods known in the art, dried and cured by irradiating with ultraviolet light or the like. Thereafter, the curable acrylate adhesive is coated on either one or both of the surface of the cured photothermal conversion layer 4 and the surface of the substrate 2 on the non-ground side. The photothermal conversion layer 4 and the substrate 2 are attached through the curable acrylate adhesive, which is then cured to form the joining layer 3, for example, by irradiating with ultraviolet light from the carrier side, whereby a layered body can be formed. The formation of such a layered body is preferably performed under vacuum to prevent air from entering between layers. This can be attained by, for example, by modifying a vacuum adhesion device such as that described in U.S. Pat. No. 6,221,454 (Kazuta et al.)

The layered body is preferably designed such that it is free from the invasion of water used during grinding of the substrate, has an adhesive strength between layers so as not to cause dropping off of the substrate, and has an abrasion resistance so as to prevent the photothermal conversion layer from being abraded by the water flow (slurry) containing dusts of the ground substrate.

A thinned substrate can be manufactured by the method comprising preparing a layered body formed as above, grinding the substrate, to a desired thickness, applying radiation energy to the photothermal conversion layer through the light transmitting carrier to decompose the photothermal conversion layer and thereby to separate the ground substrate from the light transmitting carrier, and peeling the joining layer from the substrate.

In one aspect, the method of the present disclosure is described below by referring to the drawings. In the following, a laser beam is used as the radiation energy source and a silicon wafer is used as the substrate to be ground, however, the present disclosure is not limited thereto.

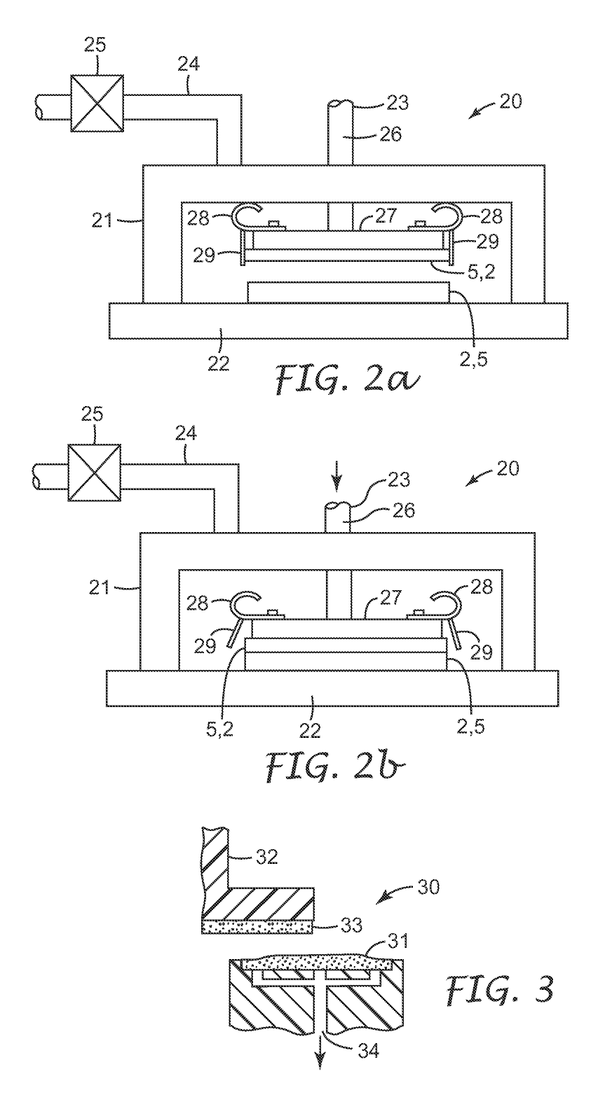

FIG. 2 shows a cross-sectional view of a vacuum adhesion device suitable for the production of the layered body of one embodiment of the present disclosure. A vacuum adhesion device 20 comprises a vacuum chamber 21; a supporting part 22 provided in the vacuum chamber 21, on which either one of a substrate 2 to be ground (silicon wafer) or a carrier 5 is disposed; and holding/releasing means 23 provided in the vacuum chamber 21 and movable in the vertical direction at the upper portion of the supporting part 22, which holds the other one of the support 5 or the silicon wafer 2. The vacuum chamber 21 is connected to a pressure reducing device 25 via pipe 24, so that the pressure inside the vacuum chamber 21 can be reduced. The holding/releasing means 23 has a shaft 26 movable up and down in the vertical direction, a contact surface part 27 provided at the distal end of the shaft 26, leaf springs 28 provided in the periphery of the contact surface part 27, and holding claws 29 extending from each leaf spring 28. As shown in FIG. 2(a), when the leaf springs are in contact with the upper surface of the vacuum chamber 21, the leaf springs are compressed and the holding claws 29 are directed toward the vertical direction to hold the support 5 or the wafer 2 at peripheral edges. On the other hand, as shown in FIG. 2(b), when the shaft 26 is pressed down and the carrier 5 or the wafer 2 is in close proximity to the wafer 2 or the carrier 5 respectively disposed on the supporting part, the holding claws 29 are released together with the leaf springs 28 to superimpose the carrier 5 and the wafer 2.

Using this vacuum adhesion device 20, the layered body can be manufactured as follows. First, as described above, a photothermal conversion layer is provided on a carrier 5. Separately, a wafer to be layered is prepared. On either one or both of the wafer 2 and the photothermal conversion layer of the carrier 5, an adhesive for forming a joining layer is applied. The thus-prepared carrier 5 and wafer 2 are disposed in the vacuum chamber 21 of the vacuum adhesion device 20 as shown in FIG. 2(a), the pressure is reduced by the pressure reducing device, the shaft 26 is pressed down to layer or laminate the wafer as shown in FIG. 2(b) and after opening to air, the adhesive is cured, if desired, to obtain a layered body.

FIG. 3 shows a partial cross-sectional view of a grinding device useful in an embodiment of the disclosure. The grinding device 30 comprises a pedestal 31 and a grinding wheel 33 mounted on the bottom end of a spindle 32 and capable of rotation. A suction port 34 is provided adjacent the pedestal 31 and the suction port 34 is connected to a pressure reducing device (not shown), whereby a material to be ground is suctioned and fixed on the pedestal 31 of the grinding device 30. The layered body 1 of the present disclosure as shown in FIG. 1 is prepared and used as a material to be ground. The carrier side of the layered body 1 is mounted on the pedestal 31 of the grinding device 30 and fixed by suction using a pressure-reducing device. Thereafter, while feeding a fluid flow (such as water or any solution known useful in wafer grinding), the grinding wheel 33 under rotation is brought into contact with the layered body 1, thereby performing the grinding. The grinding can be performed to a thin level of 150 μm or less, preferably 50 μm or less, more preferably 25 μm or less.

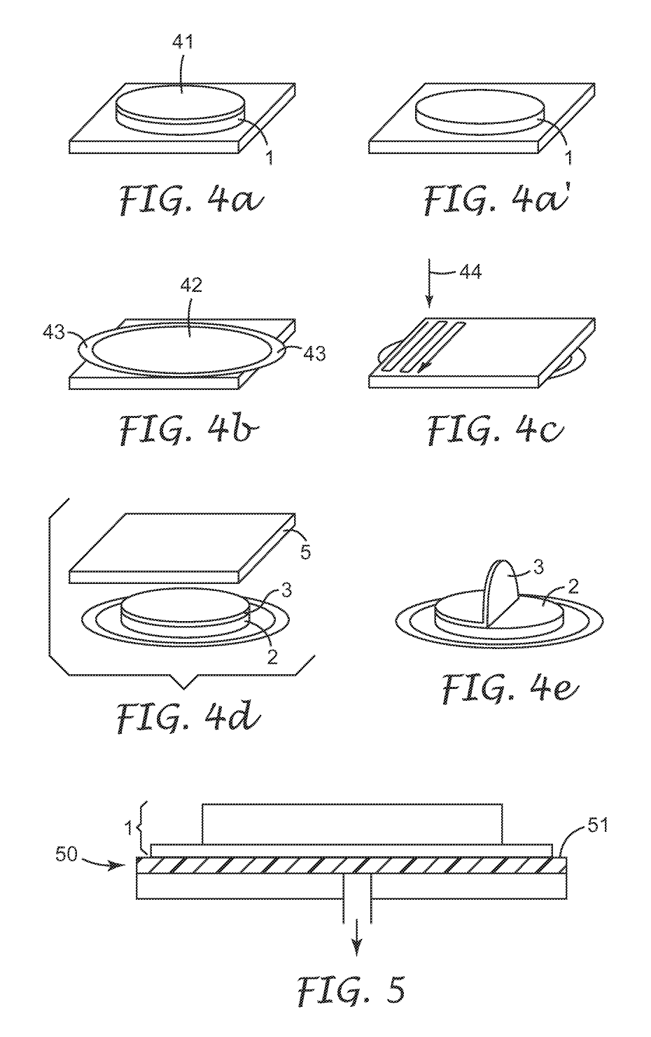

After grinding to the desired level, the layered body 1 is removed and conveyed to subsequent steps, where the separation of the wafer and the carrier by irradiation with a laser beam and the peeling of the joining layer from the wafer are performed. FIG. 4 shows a drawing of the steps of separating the carrier and peeling of the joining layer. First, by taking account of the final step of dicing, a die bonding tape 41 is disposed, if desired, on the ground surface of the wafer side of the layered body 1 (FIG. 4(a)) or the die bonding tape 41 is not disposed (FIG. 4(a′)), and thereafter, a dicing tape 42 and a dicing frame 43 are disposed (FIG. 4(b)). Subsequently, a laser beam 44 is irradiated from the carrier side of the layered body 1 (FIG. 4(c)). After the irradiation of the laser beam, the carrier 5 is picked up to separate the carrier 5 from the wafer 2 (FIG. 4(d)). Finally, the joining layer 3 is separated by peeling to obtain a thinned silicon wafer 2 (FIG. 4(e)).

Usually, a semiconductor wafer such as silicon wafer is subjected to chamfering called beveling so as to prevent edges from damage due to impact. That is, the corners at edge parts of a silicon wafer are rounded. When a liquid adhesive is used as the joining layer and coated by spin coating, the joining layer is spread to the edge parts and the adhesive is exposed to edge parts of the grinding surface. As a result, in disposing a dicing tape, not only the ground wafer but also the exposed adhesive come into contact with the pressure-sensitive adhesive of the dicing tape. When the adhesion of the dicing tape used is strong, the joining layer is sometimes difficult to separate. In such a case, it is preferred to previously remove a part of the exposed adhesive before disposing a dicing tape and a dicing frame. For the removal of the exposed adhesive at edge parts, radiation energy or a CO₂ laser (wavelength of 10.6 μm) can be used which the adhesive can sufficiently absorb.

FIG. 5 shows a cross-sectional view of a layered body fixing device which can be used, for example, in the step of irradiating, such as with a laser beam in one aspect of the disclosure. The layered body 1 is mounted on a fixing plate 51 such that the carrier comes as the upper surface with respect to the fixing device 50. The fixing plate 51 is made of a porous metal such as sintered metal or a metal having surface roughness. The pressure is reduced from the lower part of the fixing plate 51 by a vacuum device (not shown), whereby the layered body 1 is fixed by suction onto the fixing plate 51. The vacuum suction force is preferably strong enough not to cause dropping in the subsequent steps of separating the support and peeling of the joining layer. A laser beam is used to irradiate the layered body fixed in this manner. For emitting the laser beam, a laser beam source having an output high enough to cause decomposition of the heat decomposable resin in the photothermal conversion layer at the wavelength of light absorbed by the photothermal conversion layer is selected, so that a decomposition gas can be generated and the support and the wafer can be separated. For example, a YAG laser (wavelength of 1,064 nm), a second harmonic YAG laser (wavelength: 532 nm) and a semiconductor laser (wavelength: from 780 to 1,300 nm) can be used.

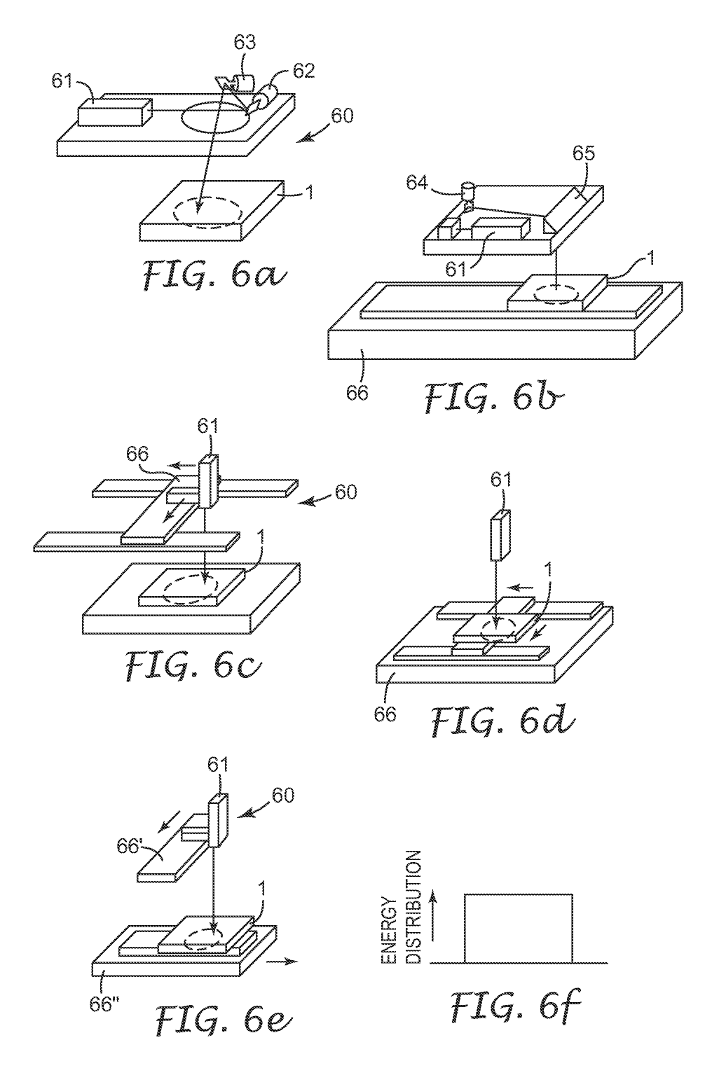

As the laser irradiation device, a device capable of scanning a laser beam to form a desired pattern on the irradiated surface and capable of setting the laser output and the beam moving speed is selected. Also, in order to stabilize the processing quality of the irradiated material (layered body), a device having a large focus depth is selected. The focus depth varies depending on the dimensional precision in the design of device and is not particularly limited but the focus depth is preferably 30 μm or more. FIG. 6 shows a perspective view of a laser irradiation device which can be used in the present disclosure. The laser irradiation device 60 of FIG. 6(a) is equipped with a galvanometer having a biaxial configuration composed of the X axis and the Y axis and is designed such that a laser beam oscillated from a laser oscillator 61 is reflected by the Y axis galvanometer 62, further reflected by the X axis galvanometer 63 and irradiated on the layered body 1 on the fixing plate. The irradiation position is determined by the directions of the galvanometers 62 and 63. The laser irradiation device 60 of FIG. 6(b) is equipped with a uniaxial galvanometer or a polygon mirror 64 and a stage 66 movable in the direction orthogonal to the scanning direction. A laser beam from the laser oscillator 61 is reflected by the galvanometer or polygon 64, further reflected by a hold mirror 65 and irradiated on the layered body 1 on the movable stage 66. The irradiation position is determined by the direction of the galvanometer or polygon 64 and the position of the movable stage 66. In the device of FIG. 6(c), a laser oscillator 61 is mounted on a movable stage 66 which moves in the biaxial direction of X and Y, and a laser is irradiated on the entire surface of the layered body 1. The device of FIG. 6(d) comprises a fixed laser oscillator 61 and a movable stage 66 which moves in the biaxial direction of X and Y. The device of FIG. 6(e) has a constitution such that a laser oscillator 61 is mounted on a movable stage 66′ which can move in the uniaxial direction and a layered body 1 is mounted on a movable stage 66″ which can move in the direction orthogonal to the movable stage 66′.

When there is concern about damaging the wafer of the layered body 1 by the laser irradiation, a top hat beam form (see FIG. 6(f)) having a steep energy distribution and reduced leakage energy to the adjacent region is preferably formed. The beam form may be changed by any known method, for example, by (a) a method of deflecting the beam by an acousto-optic device, a method of forming a beam using refraction/diffraction, or (b) a method of cutting the broadening portion at both edges by using an aperture or a slit.

The laser irradiation energy is determined by the laser power, the beam scanning speed and the beam diameter. For example, the laser power that can be used is, but not limited to, from 0.3 to 100 watts (W), the scanning speed is from 0.1 to 40 meters/second (m/s), and the beam diameter is from 5 to 300 μm or more. In order to increase the speed of this step, the laser power is enhanced and thereby the scanning speed is increased. Since the number of scans can be further reduced as the beam diameter becomes larger, the beam diameter may be increased when the laser power is sufficiently high.

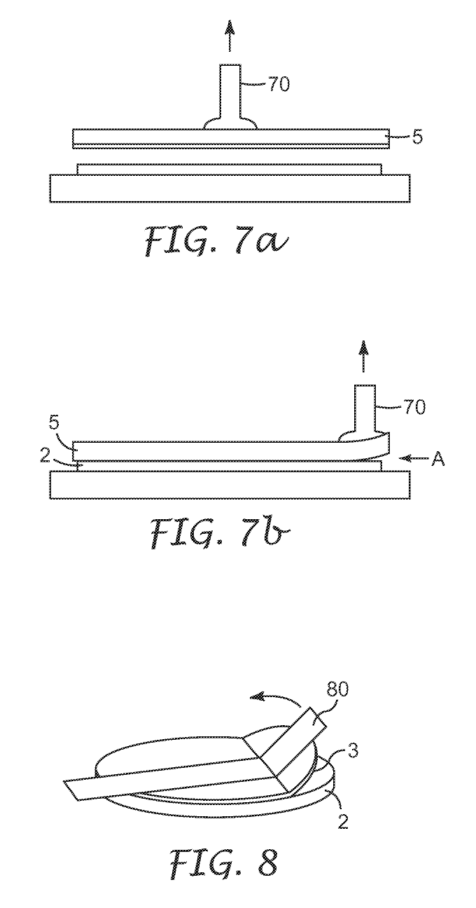

After the laser irradiation, the carrier is separated from the wafer and for this operation a general pick-up using a vacuum is used. The pick-up is a cylindrical member connected to a vacuum device having a suction device at the distal end. FIG. 7 shows a schematic view of a pick-up for use in the separation operation of the wafer and the carrier. In the case of FIG. 7(a), the pick-up 70 is generally in the center of the carrier 5 and picked up in a generally vertical direction, thereby peeling off the carrier. Also, as shown in FIG. 7(b), the pick-up 70 is at the edge part of the carrier 5 and by peeling while blowing a compressed air (A) from the side to enter air between the wafer 2 and the carrier 5, the carrier can be more easily peeled off.

After removing the carrier, the joining layer on the wafer is removed. FIG. 8 is a schematic view showing how the joining layer is peeled. For the removal of the joining layer 3, preferably, an adhesive tape 80 for removing the joining layer, which can create a stronger adhesive bond with joining layer 3 than the adhesive bond between the wafer 2 and the joining layer 3, can be used. Such an adhesive tape 80 is placed to adhere onto the joining layer 3 and then peeled in the arrow direction, whereby the joining layer 3 is removed.

Finally, a thinned wafer remains in the state of being fixed to a dicing tape or a die frame with or without a die bonding tape. This wafer is diced in a usual manner, thereby completing a chip. However, the dicing may be performed before the laser irradiation. In such a case, it is also possible to perform the dicing step while leaving the wafer attached to the support, then subject only the diced region to the laser irradiation and separate the support only in the diced portion. The present disclosure may also be applied separately to a dicing step without using a dicing tape, by re-transferring through a joining layer the ground wafer onto a light transmitting carrier having provided thereon a photothermal conversion layer.

The methods disclosed herein allow the layered body to be subjected to higher temperature processes than prior art methods. In the manufacture of semiconductor wafers, the instant method allows subsequent processing steps. One such exemplary processing step can be sputtering techniques such as, for example, metal deposition processing for electrical contacts. Another such exemplary processing step can be dry etching techniques such as, for example, reactive ion etching for creating vias in the substrate. Another such exemplary processing step can be thermocompression bonding such as, for example, bonding an additional layer to the wafer. Embodiments of the disclosure are advantageous because the layered body can be subjected to these processing steps while still allowing the joining layer to be easily removed from the ground substrate (wafer).

In some embodiments the layered body comprising a cured adhesive joining layer can be subjected to temperatures of 200° C. and even 250° C. Embodiments of this disclosure provide that the adhesive can be heated to at least 250 degrees Celsius for at least one hour and still maintain its mechanical integrity and adhesion while also able to be cleanly removed from a substrate.

The present disclosure is effective, for example, in the following applications.

### 1. Layered CSP (Chip Scale Package) for High-Density Packaging

The present disclosure is useful, for example, with a device form called system-in-package where a plurality of Large Scale Integrated (LSI) devices and passive parts are housed in a single package to realize multifunction or high performance, and is called a stacked multi-chip package. According to the present disclosure, a wafer of 25 μm or less can be reliably manufactured in a high yield for these devices.

### 2. Through-Type CSP Requiring High Function and High-Speed Processing

In this device, the chips are connected by a through electrode, whereby the wiring length is shortened and the electrical properties are improved. To solve technical problems, such as formation of a through hole for forming a through electrode and embedding of copper in the through hole, the chip may be further reduced in the thickness. In the case of sequentially forming chips having such a configuration by using the layered body of the present disclosure, an insulating film and a bump (electrode) may be formed on the back surface of the wafer and the layered body needs resistance against heat and chemicals. Even in this case, when the above-described support, photothermal conversion layer and joining layer are selected, the present disclosure can be effectively applied.

### 3. Thin Compound Semiconductor (E.G., GaAs) Improved in Heat Radiation Efficiency, Electrical Properties, and Stability

Compound semiconductors such as gallium arsenide are being used for high-performance discrete chips, laser diode and the like because of their advantageous electrical properties (high electron mobility, direct transition-type band structure) over silicon. Using the layered body of the present disclosure and thereby reducing the thickness of the chip increases the heat dissipation efficiency thereof and improves performance. At present, the grinding operation for thickness reduction and the formation of an electrode are performed by joining a semiconductor wafer to a glass substrate as the carrier using a grease or a resist material. Therefore, the joining material may be dissolved by a solvent for separating the wafer from the glass substrate after the completion of processing. This is accompanied with problems that the separation requires more than several days time and the waste solution should be treated. These problems can be solved when the layered body of the present disclosure is used.

### 4. Application to Large Wafer for Improving Productivity

In the case of a large wafer (for example, a 12 inch-diameter silicon wafer), it is very important to separate the wafer and the carrier easily. The separation can be easily performed when the layered body of the present disclosure is used, and therefore, the present disclosure can be applied also to this field.

### 5. Thin Rock Crystal Wafer

In the field of rock crystal wafer, the thickness reduction of a wafer is required to increase the oscillation frequency. The separation can be easily performed when the layered body of the present disclosure is used, and therefore, the present disclosure can be applied also to this field.

### 6. Thin Glass for Liquid Crystal Display

In the field of liquid crystal display, the thickness reduction of the glass is desired to reduce the weight of the display and it is desired that the glass be uniform thickness. The separation can be easily performed when the layered body of the present disclosure is used, and therefore, the present disclosure can be applied also to this field.

### EXAMPLES

### Test Methods

### Bubble Formation and Reduction

An adhesive sample, about 6 g, was applied to a 100 mm×100 mm piece of a solder ball bumped, semiconductor wafer using a syringe. The wafer piece comprised a flat polyimide surface with a regular array of solder balls, each about 85 microns in diameter. The adhesive coating thickness was reduced to about 120 microns via spinning at about 600 rpm for 25 seconds using a spin coater. The coated wafer piece was then transferred to glass chamber and the pressure was reduced using a vacuum pump. While the pressure was being reduced, the adhesive coating was visually observed. The number of bubbles was monitored, whether or not they popped by the time the pressure had reached 0.8 torr in the chamber. During the test, it took about three minutes to reach 0.8 torr. Results are in Table 1.

### Number Average Molecular Weight Measurements

Number average molecular weights of the perfluoropolyether compounds were measured by end-group analysis using standard fluorine and proton NMR techniques.

### Materials

Materials

| Abbreviation or Trade Name | Description |
|---|---|
| F-1 | Fluoro diacrylate, 1H, 1H ,6H ,6H-Perfluoro-1,6-hexyl |
| | diacrylate (CH₂═CHCOOCH₂C₄F₈CH₂OCOCH═CH₂), |
| | available from Exfluor Research Corporation, Austin, |
| | Texas. Used as received. |
| FPE-2 | Fluoropolyether diacrylate, |
| | CH₂═CHCOOCH₂—CF(CF₃)—O—[CF₂CF(CF₃)O]n- |
| | C₄F₈—O—[CF(CF₃)CF₂—O]n-CF(CF₃)—CH₂OCOCH═CH₂, |
| | having a 2,280 g/mol number average |
| | molecular weight (Mₙ). Prepared as described below. |
| FPE-3 | Fluoropolyether diacrylate, |
| | CH₂═CHCOOCH₂—CF(CF₃)—O—[CF₂CF(CF₃)O]n- |
| | C₄F₈—O—[CF(CF₃)CF₂—O]n-CF(CF₃)—CH₂OCOCH═CH₂, |
| | having a 1,546 g/mol Mₙ. Prepared |
| | as described below. |
| FPE-4 | Fluoropolyether diacrylate, |
| | CH₂═CHCOOCH₂—CF₂O—[(CF₂CF₂O)m(CF₂O)n]- |
| | CF₂—CH₂OCOCH═CH₂, |
| | having a 2,100 g/mol Mₙ, wherein m/n is about 0.9 Prepared as |
| | described below. |
| FPE-5 | Fluoropolyether acrylate, oligomeric |
| | hexafluoropropylene oxide ethanolamidol acrylate, |
| | having a 1,300 g/mol Mₙ. Prepared as described below. |
| FPE-6 | Fluoropolyether methacrylate, oligomeric |
| | hexafluoropropylene oxide ethanolamidine methacrylate, |
| | having a 1,380 g/mol Mₙ. Prepared as described below. |
| Ebecryl 3708 | A modified bisphenol A epoxy diacrylate, available |
| | under the trade designation “EBECRYL 3708” from |
| | Cytec Industries, Inc., Woodland Park, New Jersey. |
| SR 833S | Tricyclodecane dimethanol diacrylate, available under |
| | the trade designation “SR833-S” from Sartomer USA, |
| | LLC, Exton, Pennsylvania. |
| Benzyl Acrylate | Benzyl acrylate, available under the trade designation |
| | “V-160” from Osaka Organic Chemical Industry Ltd., |
| | Osaka City, Japan. |
| Irgacure 819 | A photoinitiator, Bis(2,4,6-trimethylbenzoyl)- |
| | phenylphosphineoxide, available under the trade |
| | designation “IRGACURE 819” from BASF Corporation, |
| | Florham Park, New Jersey. |
| Ebecryl 350 | A silicone diacrylate, available under the trade |
| | designation “EBECRYL 350” from Cytec Industries, Inc. |
| Tegorad 2250 | A radically crosslinkable flow, wetting and glide |
| | additive, available under the trade designation |
| | “TEGORAD 2250” from Evonik Industries, Essen, |
| | Germany. |
| Foamex N | Defoamer concentrate based on dimethyl polysiloxane, |
| | contains fumed silica, available under the trade |
| | designation “TEGO FOAMEX N” from Evonik |
| | Industries. |
| Foamtrol 110 | Liquid defoamer, siloxane based, available under the |
| | trade designation “FOAMTROL 110” from Munzing |
| | Corporation, Heilbronn, Germany. |
| Zonyl FSO 100 | An ethoxylated nonionic fluorosurfactant, available |
| | under the trade designation “ZONYL FSO-100” from EI |
| | DuPont de Nemours & Co. Wilmington, Delaware. |
| Foamkill 649 | Non silicone based defoamer, available under the trade |
| | designation “FOAMKILL 649” from Crucible Chemical |
| | Company, Greenville, South Carolina. |
| Zonyl FSN 100 | A water-soluble, ethoxylated nonionic fluorosurfactant |
| | that contains no solvent, available under the trade |
| | designation “ZONYL FSN 100” from EI DuPont de |
| | Nemours & Co. |
| Modaflow 2100 | An acrylic copolymer surfactant, flow and wetting aid, |
| | defoamer, available under the trade designation |
| | “MODAFLOW 2100” from Cytec Industries Inc., |
| | Woodland Park, New Jersey. |

### Preparation of Fluoropolyether diacrylate (FPE-2)

Oligomeric hexafluoropropylene oxide diacrylate having a 2,280 g/mol Mₙ (Fluoropolyether diacrylate, FPE-2) was prepared as follows. In a 600 ml Parr™ reactor was charged 47 g, 0.24 mol perfluorosuccinyl fluoride (available from Exfluor Research Corporation, Austin, Tex.), 7 g, 0.12 mol KF and 100 g of tetraglyme (available from Sigma-Aldrich, St. Louis, Mo.). The mixture was cooled to 0° C. followed by addition of 548 g, 3.3 mol hexafluoropropylene oxide (available from EI DuPont de Nemours & Co., Wilmington, Del.) over four hours as described in U.S. Pat. No. 3,114,778. A total of six reactions were completed, combined, reacted with excess methanol and water washed to isolate 2,540 g oligomeric hexafluoropropylene oxide dimethyl ester having a Mₙ of 2,400 g/mol. A 5-L, 3-neck round bottom flask equipped with a mechanical stirrer and nitrogen bubbler was charged with 1 kg of 1,2-dimethoxy ethane (available from Sigma-Aldrich), 36 g, 0.95 mol sodium borohydride followed by addition of 750 g, 0.31 mol oligomeric hexafluoropropylene oxide dimethyl ester over one hour and heated to 86° C. for two hours. The mixture was cooled to 25° C. and 250 g of 50% sulfuric acid was added and 702 g of oligomeric hexafluoropropylene oxide diol was isolated. To a 500 ml, 3-neck, round bottom flask was added 100 g, 0.04 mol oligomeric hexafluoropropylene oxide diol, 9.4 g, 0.09 mol triethylamine (available from Sigma-Aldrich) and 100 g methyl-t-butyl ether and stirred. Addition of 8.4 g, 0.09 mol acryloyl chloride (available from Aldrich) was accomplished over thirty minutes with a slight reflux and precipitate formation. Next, 200 g Fluorinert FC77 (available from 3M Company, St. Paul, Minn.) was added and the solution was filtered through a extraction column (available under the trade designation “PREPSEP” from Fisher Scientific Company, L.L.C, Hampton, N.H.) to filter out the salt byproduct. The solution was placed on a rotary evaporator and stripped to end point conditions of 50° C./10 torr. Oligomeric hexafluoropropylene oxide diacrylate 75 g, 0.03 mol having a 2,280 g/mol Mₙ was recovered for a 75% yield, as confirmed by FTIR and hydrogen and fluorine NMR.

### Preparation of Fluoropolyether diacrylate (FPE-3)

Oligomeric hexafluoropropylene oxide diol diacrylate having a Mₙ of 1,546 g/mol (Fluoropolyether diacrylate, FPE-3) was prepared as described for the preparation of FPE-2 except, 85 g, 0.44 mol perfluorosuccinyl fluoride, 15 g, 0.26 mol KF, 124 g of tetraglyme and 489 g, 2.95 mol hexafluoropropylene oxide was used. A total of two reactions were completed combined, reacted with excess methanol, water washed to isolate 979 g oligomeric hexafluoropropylene oxide dimethyl ester having a Mₙ of 1,429 g/mol. Reduction and conversion to diacrylate was done as described for the preparation of FPE-2 to obtain oligomeric hexafluoropropylene oxide having a Mₙ of 1,546 g/mol. A similar yield was obtained for FPE-3 as that of FPE-2.

### Preparation of Fluoropolyether diacrylate (FPE-4)

Oligomeric tetrafluoroethylene oxide/difluoromethylene oxide diacrylate having a 2,100 g/mol Mₙ (Fluoropolyether diacrylate, FPE-4) was prepared by reducing a perfluoropolyether dimethyl ester having a Mₙ of 2,000 g/mol (available under the trade designation “FOMBLIN Z-DEAL” from Solvey Solexis, Milan, Italy) with sodium borohydride in tetrahydrofuran, as described for the preparation of FPE-2. The perfluoropolyether diol was reacted with acryloyl chloride as described for the preparation of FPE-2 to give oligomeric tetrafluoroethylene oxide/difluoromethylene oxide diacrylate having a Mₙ of 2,100 g/mol. A similar yield was obtained for FPE-4 as that of FPE-2.

### Preparation of Fluoropolyether acrylate (FPE-5)

Oligomeric hexafluoropropylene oxide ethanolamidol acrylate having a 1,300 g/mol Mₙ (Fluoropolyether diacrylate, FPE-5) was prepared as described for the preparation of FPE-2 except, 83 g, 0.5 mol pentafluoropropionyl fluoride (available from SynQuest Labs. Inc., Alachua, Fla.) 14 g, 0.24 mol KF, 100 g of tetraglyme and 500 g, 3.0 mol hexafluoropropylene oxide was used. Reaction with excess methanol and water washing gave 540 g oligomeric hexafluoropropylene oxide methyl ester having a Mₙ of 1,200 g/mol. A 1-L, 3-neck round bottom flask, equipped with a mechanical stirrer and nitrogen bubbler, was charged with 500 g, 0.42 mol oligomeric hexafluoropropylene oxide methyl ester, 33 g, 0.54 mol ethanolamine and stirred under nitrogen at 75° C. for 24 hours. The reaction was terminated as FTIR analysis confirmed the disappearance of the ester peak at 1,790 cm⁻¹ along with the appearance of the amide peak at 1,710 cm⁻¹. The product was dissolved in 400 g of methyl tert-butyl ether and was stirred with 50 ml 2N aqueous HCl for 15 minutes at room temperature then place in a separatory funnel to split the aqueous and organic phases, the aqueous phase being removed from the funnel. The organic phase was next stirred with 80 ml 2% aqueous sodium carbonate for 20 minutes. The organic phase was next stirred with 50 ml 10% aqueous sodium chloride for 20 minutes. The organic phase was dried over 10 g magnesium sulfate and filtered using a Buchner funnel. The organic phase was stripped of solvent on a rotary evaporator at 55° C./20 torr producing the oligomeric hexafluoropropylene oxide amidol. To a 500 ml, 3-neck, round bottom flask was added 200 g, 0.16 mol oligomeric hexafluoropropylene oxide amidol, 17.1 g, 0.17 mol triethylamine (available from Aldrich) and 150 g methyl-t-butyl ether and stirred. Addition of 15.3 g, 0.17 mol acryloyl chloride (available from Aldrich) was over ten minutes with a slight reflux and precipitate formation. Next, was added 200 g Fluorinert FC77 available from 3M Company and the solution was filtered through an extraction column (available under the trade designation “PREPSEP” from Fisher Scientific Company, L.L.C.) to filter out the salt byproduct. The solution was placed on a rotary evaporator and stripped to end point conditions of 50° C./10 torr. The final product, oligomeric hexafluoropropylene oxide amidolacrylate, 169 g (82% yield), 0.13 mol, having a Mₙ of 1,300 g/mol.

### Preparation of Fluoropolyether methacrylate (FPE-6)

Oligomeric hexafluoropropylene oxide ethanolamidine methacrylate of 1,380 g/mol Mₙ (Fluoropolyether methacrylate FPE-6) was prepared starting with the oligomeric hexafluoropropylene oxide amidol described in the preparation of FPE-5. To a 500 ml, 3-neck, round bottom flask was added 165 g, 0.14 mol oligomeric hexafluoropropylene oxide amidol, 17 g, 0.17 mol triethylamine (available from Aldrich) and 244 g methyl-t-butyl ether and stirred. Addition of 18 g, 0.17 mol methacryloyl chloride (available from Aldrich) was over ten minutes with a slight reflux and precipitate formation. Next, 70 g of a 10% aqueous HCl solution was added and the mixture was stirred, followed by separation and removal of the aqueous phase via a reparatory funnel. The organic phase was next stirred with 90 g 25% aqueous sodium carbonate for 20 minutes. The organic phase was placed on a rotary evaporator and stripped to end point conditions of 50° C./10 torr. The final product, oligomeric hexafluoropropylene oxide amidolmethacrylate 150 g (78% yield), 0.11 mol with a 1,380 g/mol Mₙ was confirmed by FTIR and hydrogen and fluorine NMR.

### Examples 1 Through 5 and Comparative Examples CE-6 Through CE-13

The examples and comparative examples consist of an adhesive formulation which was subsequently mixed with various additives. The following adhesive formulation was made for additive testing: 63.1 wt. % Ebecryl 3708, 13.4 wt. % SR 833S, 20.9 wt. % benzyl acrylate, 0.6 wt. % Irgacure 819, 1 wt. % Ebecryl 350 and 1 wt. % Tegorad 2250.

Additives were evaluated by addition to above adhesive formulation at the indicated level, see Table 1 for wt. % addition. Each sample was then degassed in a vacuum oven at 40° C. and <0.3 torr. Using the Bubble Formation and Reduction test method described above, Examples 1-5 and Comparative Examples CE-6 through CE-13 were tested. Results are shown in Table 1.

TABLE 1
Effect of Additives on bubble formation in adhesive coating under vacuum

| | | Additive | |
|---|---|---|---|
| | Additive | Amount | Bubble Formation and Reduction Test |
| Sample | Type | (wt. %) | Observations |
| Example | FPE2 | 0.1 | <10 bubbles, popped before reaching |
| 1 | | | 0.8 torr pressure |
| Example | FPE3 | 0.1 | <10 bubbles, popped before reaching |
| 2 | | | 0.8 torr pressure |
| Example | FPE4 | 0.1 | <10 bubbles, popped before reaching |
| 3 | | | 0.8 torr pressure |
| Example | FPE5 | 0.1 | <10 bubbles, popped before reaching |
| 4 | | | 0.8 torr pressure |
| Example | FPE6 | 0.1 | <10 bubbles, popped before reaching |
| 5 | | | 0.8 torr pressure |
| CE-6 | No | — | Many large bubbles, bubbles did not |
| | Additive | | pop |
| CE-7 | Foamex | 0.1 | Many large bubbles, bubbles did not |
| | | | pop |
| CE-8 | Foamtrol | 0.1 | Many large bubbles, bubbles did not |
| | | | pop |
| CE-9 | Zonyl | 0.3 | Many large bubbles, bubbles did not |
| | FSO | | pop |
| CE-10 | Foamkill | 1 | Many large bubbles, bubbles did not |
| | | | pop |
| CE-11 | Zonyl | 0.5 | Many large bubbles, bubbles did not |
| | FSN | | pop |
| CE-12 | Modaflow | 0.6 | Many large bubbles, bubbles did not |
| | 2100 | | pop |
| CE-13 | F-1 | 0.1 | Many large bubbles, bubbles did not |
| | | | pop |

What is claimed is:

1. A curable adhesive composition comprising:
a) at least one free radically polymerizable oligomer component;
b) optionally at least one diluent monomer;
c) 0.05 to 1.0 wt. % of at least one perfluorinated ether monomer; and
d) a photoinitiator.

2. A curable adhesive composition comprising:
a) 30-99.95 wt. % of at least one free radically polymerizable oligomer component;
b) 0 to 70 wt. % range of at least one diluent monomer;
c) 0.05 to 1.0 wt. % of a perfluorinated ether monomer;
d) 0.1 to 5 wt. % range of a photoinitiator, relative to component a), b) and c).

3. The curable adhesive composition of claim 1, wherein the perfluorinated ether monomer is of the formula:
(R_{f})-(L²-Z²)ₑ (2)
wherein R_{f} is a perfluoropolyether group; L² is a (hetero)hydrocarbyl linking group; and Z² is a free-radically polymerizable group; and e is 1 or 2.

4. The curable composition of claim 2 wherein the perfluoropolyether group is selected —(CₚF₂ₚO)—, —(CF(R_{f}¹)O)—, —(CF(R_{f}¹)CₚF₂ₚO)—, —(CₚF₂ₚCF(R_{f}¹)O)—, —(CF₂CF(R_{f}¹)O)—, or combinations thereof, p is an integer of 1 to 10 and R_{f}¹ is a fluorine, a perfluoroalkyl group, perfluoroether group, perfluoropolyether, or a perfluoroalkoxy group.

5. The composition of claim 1 wherein R_{f} is a monovalent group selected from CF₃O(C₂F₄O)ₐCF₂—, C₃F₇O(CF₂CF₂CF₂O)ₐCF₂CF₂—, and C₃F₇O(CF(CF₃)CF₂O)ₐCF(CF₃)— wherein “a” has an average value of 0 to 50.

6. The composition of claim 1 wherein R_{f} is a divalent group selected from —CF₂O(CF₂O)_{b}(C₂F₄O)ₐCF₂—, —CF₂CF₂O(C₃F₆O)ₐCF₂CF₂—, —(CF₂)₃O(C₄F₈O)ₐ(CF₂)₃—, —CF₂O(C₂F₄O)ₐCF₂—, and —CF(CF₃)(OCF₂CF(CF₃))_{b}OCₜF₂ₜO(CF(CF₃)CF₂O)ₐCF(CF₃)—, wherein a and b independently average value of 0 to 50 and the sum (a+b) has an average value of 1 to 50 or 4 to 40; and t is an integer of 2 to 6.

7. The curable composition of claim 1 wherein the oligomer component is selected from (meth)acrylated epoxy oligomers, (meth)acrylated urethanes oligomers, (meth)acrylated polyethers oligomers, (meth)acrylated polyesters oligomers, (meth)acrylated polybutadiene oligomers and (meth)acrylated polyolefin oligomers.

8. The curable composition of claim 1, wherein the diluent monomer has a T_{g} of less than 30° C.

9. The curable composition of claim 1, wherein the diluent monomer is used in amounts sufficient such that the curable composition has a viscosity of less than 10,000 cps.

10. The curable composition of claim 1 wherein free-radically polymerizable oligomer is of the general formula
R^{Olig}-(L¹-Z¹)_{d}, wherein
R^{Olig} groups include oligomeric urethanes, polyurethanes, esters, polyesters, polyethers, polyolefins, polybutadienes and epoxies;
Z¹ is a pendent, free-radically polymerizable group such as (meth)acryloyl, vinyl or alkynyl and is preferably a (meth)acrylate, and
d is greater than 1.

11. The cured composition of claim 1 of the formula: 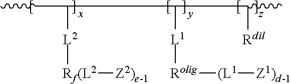
wherein subscript x is the weight percent polymerized monomer units from the perfluoropolyether monomer, subscript y is the weight percent polymerized oligomer units; and the subscript z is the weight percent of the optional diluent monomer (R^{dil}).

12. The curable composition of claim 1, further comprising a curable acrylate adhesion modifying agent.

13. The cured composition of claim 1 having a peel value less than 2 N/inch (7.0 N/dm).

14. A laminated body comprising a transmissive support and workpiece secured thereto by the cured adhesive composition of claim 1.

15. A method for manufacturing a layered body,
the layered body comprising:
a substrate to be ground;
a joining layer in contact with said substrate, said joining layer comprising the cured adhesive composition of claim 1;
a photothermal conversion layer comprising a light absorbing agent and a heat decomposable resin disposed adjacent the joining layer; and
a light transmitting carrier disposed adjacent the photothermal conversion layer,
the method comprising the steps of:
coating on the light transmitting carrier a photothermal conversion layer precursor containing a light absorbing agent and a heat decomposable resin solution or a monomer or oligomer as a precursor material of the heat decomposable resin;
drying to solidify or cure the photothermal conversion layer precursor to form a photothermal conversion layer on the light transmitting support;
applying the joining layer comprising a curable oligomer of claim 1 and a curable acrylate adhesion modifying agent to the substrate to be ground or to the photothermal conversion layer; and
joining the substrate to be ground and the photothermal conversion layer through the joining layer under reduced pressure, and curing to form the layered body.

16. A method for modifying a semiconductor wafer comprising the steps of:
applying a photothermal conversion layer comprising a light-absorbing agent and a heat decomposable resin on a light-transmitting carrier,
preparing a semiconductor wafer having a circuit face with a circuit pattern and a non-circuit face on the side opposite of the circuit face, layering the semiconductor wafer and the light-transmitting carrier through a joining layer including a curable adhesive composition of claim 1 and a curable acrylate adhesion modifying agent by placing the circuit face and said photothermal conversion layer to face each other, and irradiating light through the light-transmitting carrier to cure the joining layer, thereby forming a layered body having a non-circuit face on the outside surface,
grinding the non-circuit face of the semiconductor wafer until the semiconductor wafer reaches a desired thickness,
exposing the photothermal conversion layer to radiation through the light-transmitting carrier to decompose the photothermal conversion layer, and separating the wafer with said joining layer from the light-transmitting carrier; and
removing the joining layer from the semiconductor wafer.

17. The method of claim 16, wherein adhering the semiconductor wafer and the light-transmitting carrier through the joining layer is performed in a vacuum.

18. The method of claim 16, wherein the curable acrylate adhesion modifying agent includes a silicone polymer substituted with (meth)acrylate groups.

19. A layered body comprising:
a substrate to be ground;
a joining layer comprising the curable composition of claim 1 in contact with the substrate;
a photothermal conversion layer comprising a light absorbing agent and a heat decomposable resin disposed adjacent the joining layer; and
a light transmitting carrier disposed adjacent the photothermal conversion layer.

20. A method of providing a thin substrate comprising:
providing a layered body comprising (i) a substrate to be ground; (ii) a joining layer comprising the curable composition of claim 1 in contact with the substrate; (iii) a photothermal conversion layer comprising a light absorbing agent and a heat decomposable resin disposed adjacent the joining layer; and (iv) a light transmitting carrier disposed adjacent the photothermal conversion layer;
grinding a face of said substrate to a desired thickness; and
irradiating radiation energy through the light-transmitting support side to decompose said photothermal conversion layer, thereby causing separation into a thin substrate having the joining layer and a light-transmitting carrier, and optionally removing said cured joining layer from said ground substrate.

21. The method of claim 20, further comprising the step of dicing the ground substrate into a plurality of ground substrates.

22. The method of claim 20, wherein the substrate to be ground comprises a semiconductor wafer, the wafer having a circuit face adjacent said joining layer and a non-circuit face.
